(19) United States
(12) Patent Application Publication
(10) Pub. No.: US 2017/0276870 A1
(43) Pub. Date: Sep. 28, 2017

(54) CMOS BASED MICRO-PHOTONIC SYSTEMS

(71) Applicant: Tshwane University of Technology, Pretoria West (ZA)

(72) Inventor: Lukas Willem SNYMAN, Faerie Glen, Pretoria (ZA)

(73) Assignee: TSHWANE UNIVERSITY OF TECHNOLOGY, Pretoria West (ZA)

(21) Appl. No.: 14/110,272

(22) PCT Filed: Nov. 30, 2011
(86) PCT No.: PCT/ZA11/00090

§ 371 Date: Apr. 3, 2014

(51) Int. Cl. G02B 6/122; B81B 7/00; G02B 6/14; H04B 10/50

(52) U.S. Cl. CPC G02B 6/122; H04B 10/501; B81B 7/0067; G02B 6/14; G02B 6/1225; G02B 2006/12035

(57) ABSTRACT

This invention relates to CMOS based micro-photonic systems comprising an optical source, means for optical transmission, and a detector, wherein the optical source is capable of emitting light having a wavelength being in a range in which a nitride comprising layer of said means for optical transmission is transparent and being below a detection threshold of said detector so as to enable the generation of a micro-photonic system in silicon integrated circuit technology.

This invention relates to CMOS based micro-photonic systems

Micro-photonic systems can be used in many CMOS based applications. For example, on-chip absorption, reflection, and fluorescence sensors, micro optical-electrical-mechanical sensors, mechanical sensor technology or optical communication systems are typical applications, which require light emitting diodes, light emitting lasers, optics, fiber optic technology, or mechanical sensor technology.

The current chip based optical communication systems utilize discrete packages of group III-V and compound semiconductors that are fabricated in discrete packages and that is used in discrete form to build and compose optical fibre based optical communication systems.

A vast majority of micro-electronic devices are formed in silicon. Over the last several decades, a substantial effort has been directed to refining the reliability and manufacturability of these devices. As a result, silicon-based microelectronic devices have become dependable and inexpensive commodity items. Particularly, Complementary Metal Oxide Semiconductor (CMOS) technology has become a multi-billion industry providing the basis manufacturing technology for nearly 90% of all electronic commodities to society. Furthermore, Silicon-on-Insulator (SOI) technology is regarded as a future basis technology for combining optoelectronics technology with mainstream electronics manufacturing technology.

Furthermore, Silicon-on-Insulator (SOI) technology is regarded as a future basis technology for combining optoelectronics technology with mainstream electronics manufacturing technology and SiGe technologies are emerging as technologies to provide higher switching speed.

The current state of the art focuses on 1100 nm and above 1100 nm optical communication systems for application in CMOS and SOI, mainly as a result of compatibility with long-haul optical fibre communication networks. This approach has several limitations, since it requires the incorporation of Ge in the systems in order to realize efficient detectors, and or III-V technology using hybrid approaches in both material and processing procedures. These technologies are extremely complex and are also very expensive.

To take advantage of the existing silicon-based knowledge and infrastructure, there is a great interest in integrating active optical components into CMOS and SOI silicon technologies. Silicon, however, is an indirect band gap semiconductor material which, unlike a direct band gap semiconductor material, and current silicon light emitting devices has low photon emission efficiency. This has severe drawbacks since the optical power emission levels severely limits the maximum distance of communication in optical; fibre based communication systems, as well in free space optical communication systems.

Furthermore, Silicon-based optical sources, as a result of the poor electrical-to-optical conversion efficiency, require high driving currents. This in turn requires high CMOS circuitry layouts, which result in high capacitance and subsequent low switching speeds. Current proposed Si LED based systems also propose the utilisation of parabolic mirror structures as configured by CMOS metal over-layers in order to transfer optical radiation from the chip to the optical fibre or free space.

Accordingly, there is an opportunity in the art to provide further improvements to both silicon-based optical communication systems and silicon based micro-photonic systems.

### SUMMARY OF THE INVENTION

There is provided a micro photonic system comprising an optical source, means for optical transmission, and a detector, wherein the optical source is capable of emitting light having a wavelength being in a range in which a nitride comprising layer of said means for optical transmission is transparent and being below a detection threshold of said detector so as to enable the generation of a micro-photonic system in silicon integrated circuit technology.

The circuit technology may be complementary metal oxide semiconductor technology (CMOS) silicon integrated circuit technology.

The wavelength may be in the range between 600 nm and 900 nm.

The means for optical transmission may include an optical coupling component, an optical director component, a wave guiding component, or a reflective component, and utilizes silicon nitride or Silicon Oxi-nitride or silicon oxide layers as a light transporting medium.

The micro photonic system may further include a detector component that can enable measurement of physical and chemical parameters such as temperature, shock, motion, acceleration, light level, fluid flow, and particle counts and particle absorption and particle fluorescence, or utilizing intensity or phase contrast technology.

The light source may be an integrated Si Av LED.

The optical source may be separated from a phase contrast optical module in order to increase sensitivity, accuracy and stability in measurement.

The optical source may be an OLED device.

The optical source and the detector may form a waveguide based optical transmit receiver module including an excitation region generating excited high energy carriers, a carrier relaxation and recombination zone for the excited carriers yielding photonic emission, a photonic absorption region where incident photons as received from the waveguide generates electric current, and contacts being added to sections of the module in order either sequentially or simultaneously generated or detects photonic radiation.

The optical source may be arranged as a matrix of Si Av LEDs on a silicon substrate.

The micro photonic system may further comprise a photonic crystal being coupled to a sensor layer and/or a signal processing layer.

The optical source may be comprised of a body of a semiconductor material; a first junction region in the body formed between a first region of the body of a first doping kind and a second region of the body of a second doping kind; a second junction region in the body formed between the second region of the body and a third region of the body of the first doping kind; a terminal arrangement connected to the body for, in use, reverse biasing the first junction region into a breakdown mode and for forward biasing at least part of the second junction region to inject carriers towards the first junction region; and the device being configured so that a first depletion region associated with the reverse biased first junction region punches through to a second depletion region associated with the forward biased second junction region.

The optical source and the detector may form an optical communication system.

The optical source and the detector form plastic user card or mobile control unit platform.

According to the invention substantial progress with respect to the integration of hybrid optical sources into CMOS silicon, as well as with the development of waveguide structures that can be integrated on CMOS technology has been made.

These structures are greatly transparent for wavelengths 750-850 nm and offer much higher coupling and transfer efficiency between the optical source and the fibre or free space. Correspondingly this technology open up a whole new domain for integrating optical micro-photonic structures onto CMOS chip, either in integrated or with components hybridly integrated into the waveguide structures.

If Si LEDs are used as optical sources, silicon and silicon CMOS technology are used for optical coupling, optical directing and optical wave guiding, therefore, this offers the scope for generating complete photonic systems in CMOS technology without the use of III-V or Si—Ge technology. This prospect is considerably enhanced, if appropriate high speed avalanche based Si LEDs could be utilised in the 450 to 850 nm regime, and if appropriate wave-guiding and electro-optical structures could be developed in CMOS integrated circuitry in this wavelength regime, that standard silicon detectors with an absorption edge at 850 nm could be utilised to generate CMOS based electro-optical structures. Hence, diverse silicon optoelectronic structures could be realised that contain no foreign technology incorporated in either the CMOS design or fabrication procedures. This especially could lead to the development of so-called all-silicon “smart chips” with diverse on-board optically based sensors and electronic processing circuitry.

### BRIEF DESCRIPTION OF THE DRAWINGS

FIG. 1 to FIG. 46 show embodiments of the invention.

FIG. 1: Schematic diagram of a CMOS-based micro-photonic system that can be realized by utilising a hybrid package approach with an optical source and distant detectors on the same chip and directional emission of light with light reflect within the CMOS package cavity.

FIG. 2: Schematic diagram of a CMOS-based micro-photonic system that can be realized by utilising a hybrid package approach with an optical source and directional emission on the CMOS chip and an added optical module to direct and waveguide light vertically out of the CMOS structure. Here it can interact with reflective or absorptive mediums, and reflect light back to the CMOS chip for interferometric, intensity or phase contrast comparison. A separate reference path may be added between the chip LED and detector.

FIG. 3: Same concepts as in FIG. 2 (previous figure) but with an optical reference path added between the CMOS chip LED and the CMOS detector.

FIG. 4: Same concepts as in FIG. 3 (previous figure) but with the hybrid sensor module positioned distant from the CMOS optical source and the chip CMOS optical source and hybrid detector module coupled by an optical waveguide.

FIG. 5: Schematic diagram of an example CMOS-based Micro-Mechanical-Optical Sensor (MOEMS) device that can be realized with conventional CMOS integrated design with additional post processing procedures. Key constituents of such a device are an effective CMOS on-chip optical source, coupling of the source to a waveguide, CMOS compatible optical wave guiding, optical columniation, reflection from a mechanical cantilever structure and detection circuitry.

FIG. 6: Schematic diagram of a monolithic CMOS-based micro-photonic system that can be realized utilising a on chip CMOS optical source, a series of waveguides, a ring resonators and an unbalanced Mach-Zehnder type interferometer. A section of the waveguide is exposed to the environment and can induce phase and intensity contrast due to adsorption of gases and liquids in the evanescent field of the waveguide. The optical changes induced by the absorbed or adsorbed species in then detected by a on chip CMOS detector.

FIG. 7: Geometrical building blocks for a light transmitting means in a side view

FIG. 8: Effect of changing of optical emission point source in a Si LED CMOS structure showing partial emission and partial wave-guiding in the silicon nitride layer.

FIG. 9: Dedicated CMOS technology based structure for maximizing light emission from the silicon substrate.

FIG. 10: Dedicated CMOS technology based structure for facilitating directional focusing or directional slanted emission.

FIG. 11: Dedicated CMOS technology based structure for facilitating splitting of optical radiation as emitted from the silicon substrate.

FIG. 12: Cross-sectional views of dedicated structures that can be utilised for propagating light laterally in (1) the CMOS over-layers and (2) at the silicon substrate over-layer.

FIG. 13: Lateral out coupling using CMOS waveguides with optical fibers aligned at the side surface of the chip. Diverse columniation of the emitted optical radiation without the fibres.

FIG. 14: Vertical outwards coupling of optical radiation into optical fiber waveguides using trench based and over-layer post processing technology.

FIG. 15 (a) shows how adiabatic expansion of the mode field diameter can be obtained by narrowing or tapering of the core structure of the waveguide. FIG. 15 (b) shows how columniation can be obtained by adding a lens structure with curved front end surface of higher or same refractive index at the end of a waveguide.

FIG. 16 (a) to (f) show how various directed emission characteristics can be obtained by using different combinations of integrated optical source, planar or cylindrical waveguides, reflecting mirrors and refractive lenses. The structure descriptions build on previous descriptions in the previous figures.

FIGS. 17 (a) and (b) show how incident light can be manipulated and accepted into the core structures according to standard optical fibre waveguiding technology principles.

FIGS. 18 (a) and (b) shows a means of coupling an optical fibre directly to a hybridly added modulator utilising simple post processing V-groove anisotropic etching technology during various stages of the CMOS processing technology.

FIG. 19 (a) to (d) shows how various photonic micro-systems can be monolithically realised on a silicon platform utilising principles of integrated waveguide technology as illustrated in the previous figures and utilising post processing CMOS technology.

FIGS. 20 (a) and (b) respectively show plan and cross-section layouts of a integrated waveguide and two-dimensional prism structure that can be realised in CMOS or SOI technology and which will enable separation of the incident optical radiation into separate wavelengths and the electronic detection of such radiation by means of silicon detector elements.

FIG. 21 (a) shows a proposed monolithic configuration of CMOS driving and modulation control circuitry on a silicon platform and post-processed added modules optical OLED source, optical wave-guiding and optical modulation and optical columniation circuitry added on the platform.

FIG. 21 (b) shows a monolithic configuration of CMOS integrated detector configuration with integrated waveguide detection and detectors closely coupled to CMOS signal processing circuitry and designed to operate optimally at 750-850 nm wave length.

FIG. 22 shows a transmitter system on a silicon platform utilising the hybrid integration of a an OLED optical source module which is epoxied or mounted onto recessed platforms in integrated CMOS or SOI waveguides such that good coupling of higher optical power occurs into the waveguide. Hybrid optical modulator modules can also be added which has very low capacitance and enable very high modulation switching speeds of the transmitted optical radiation. The optical source emission wavelength should be in the 650-850 nm regime in order to be compatible with a same receiving module as shown in FIG. 21 (b).

FIG. 23 shows configuration of a proposed hybrid optical source modules and detector modules in order to provide; (a) a chip-to-multiple chip based free space optical communication system (b) a chip-to-chip free space communication, and (c) a chip to optical fibre based optical communication system.

FIG. 24 shows a plan schematic diagram of a CMOS waveguide based signal transmit-receive module. The module can convert electrical input signals to optical signals that are transmitted by the CMOS waveguide. Similarly, the module can convert signals that arrive by waveguide to electrical signals by means of photonic absorption processes in a silicon well. The module is optimised to operate with reverse bias avalanche technology at 450-650 nm wave length.

FIG. 25 (a) shows a plan schematic diagram of a CMOS waveguide based signal transmit-receive module. The module can convert electrical input signals to optical signals that are transmitted by the CMOS waveguide. Similarly, the module can convert signals that arrive by waveguide to electrical signals by means of photonic absorption processes in a silicon well. The module is optimised to operate at 750-850 nm wave length, which is a low loss region for CMOS based waveguides utilising silicon nitride or Silicon oxinitride. FIG. 4 (b) shows the corresponding components in cross-section view.

FIG. 26 shows a plan schematic diagram of a CMOS waveguide based signal transmit-module. The module can convert electrical input signals to optical signals that are transmitted by the CMOS waveguide. The module is optimised to operate at 750-850 nm wave length, which is a low loss region for CMOS based waveguides utilising silicon nitride or Silicon oxinitride.

FIG. 27 shows a plan schematic diagram of a CMOS waveguide based signal transmit-module. The module can convert signals that arrive by waveguide to electrical signals by means of photonic absorption processes in a silicon well. The module is optimised to operate at 750-850 nm wave length, which is a low loss region for CMOS based waveguides utilising silicon nitride or Silicon oxi-nitride. FIG. 27 (b) shows the corresponding components in cross-section view.

FIG. 28 shows a plan schematic diagram of a CMOS waveguide based signal transmit-receive module that consist of a central waveguide and separate transmit and receive modules. The module is optimised to operate at 750-850 nm wave length, which is a low loss region for CMOS based waveguides utilising silicon nitride or Silicon oxi-nitride.

FIG. 29: Schematic diagrams depicting photonic crystals with periodicity in (a) one dimension, (b) two dimensions and (c) three dimensions.

FIG. 30: (a) Cross section of a two-dimensional photonic crystal defined in a dielectric slab of finite thickness. The field distribution in the vertical direction for guided and radiation modes is shown. (b) Photonic band diagram for a two-dimensional photonic crystal defined in a single-mode slab. c denotes free space speed of light. a denotes the lattice constant. The diagram depicts the lowest three bands for the TE-like modes of the slab. The inset shows the region of the first Brillouin zone described by the dispersion diagram. (c) A unit cell of a triangular photonic crystal lattice and the phase relationships between the boundaries determined by Bloch's theorem.

FIG. 31: schematic illustration showing how a multiple processing layer configuration (MPLC) can be formed in CMOS silicon consisting of several individual processing layers stacked on top of each other. In the specific case illustrated, a passivation and slotted passivation topmost layer is stacked on a photonic crystal plane layer which is again stacked on the conventional electrical interconnect and electrical signal processing and data transfer layer. In the case of the photonic layer, a slab of higher refractive index material which can accommodate either discrete wave guides, a combination of discrete waveguides, or an entire photonic crystal layer consisting of a matrix of holes stacked in the higher refractive index material causing variation in the local refractive index of the layer.

FIG. 32: Generation of a optical bus waveguide (bus bar) in the photonic crystal layer. The illustration shows a top down view on the photonic processing plane, showing the array of holes in the higher refractive index slab. Waveguides and various individual components are formed in the photonic layer in integrated circuit format. In the specific case the concept of mixing and coupling of additional optical signal as originating from secondary optical sources into a bus optical waveguide is illustrated.

FIG. 33: Generation of an optical bus waveguide (bus bar) in the photonic crystal layer. The illustration shows a top down view on the photonic processing plane, showing the array of holes in the higher refractive index slab. Waveguides and various individual components are formed in the photonic layer in integrated circuit format. In the specific case the concept of removing certain wavelength signals from the optical bus bar by means of optical couplers and diverting them to secondary detectors are illustrated.

FIG. 34: Schematic diagram of an example CMOS-based Micro-Optical Sensor module that utilizes a nano-crystalline Si LED device in the outer layers of the module such that it couple optimally in the same plane with the photonic crystal lattice.

FIG. 35 is an embodiment of the invention where the second junction is placed deep into the depletion region of the first junction, and a particular contact and voltage biasing are applied in order to produce a energy barrier for traversing energetic carriers at the second junction.

FIG. 36 shows a projection of the average diffusion length versus energy loss transitions for electrons in the conduction band as a function of distance in the depletion layer of an abrupt p+n junction.

FIG. 37 shows a projection of how the energy of an energetic (hot) electron can be lowered when it is injected into a biased potential barrier of e second reverse biased p+n junction. The subsequent recombination of the injected electron with a high density of holes on the p-side of the junction is also shown.

FIG. 38 shows a projection of how the energy of an energetic (hot) electron can be lowered when it is injected into a biased potential barrier of e second reverse biased p+n junction. The subsequent recombination of the injected electron with a high density of holes on the p-side of the junction is also shown, when defect states are present in the junction.

FIG. 39: Plan view of a Low Voltage Modulatable Silicon Light Emitting Matrix as composed by light emitting source elements. Each light emitting source LED element can be individually addressed (power supplied) and modulated by means of two sets of metal over layer mesh networks. The addressing and coupling of signals can performed by a state of the art CMOS address and encoding configuration.

FIG. 40: Schematic diagram of a monolithic CMOS-based micro-photonic and user card system showing the generic components of such a system.

FIG. 41: Schematic diagram of a monolithic CMOS-based micro-photonic and user card system showing the generic components of such a system, and utilizing surface mount technology.

FIG. 42: Schematic diagram of a monolithic CMOS-based micro-photonic and user card system showing the generic components of such a system, and utilizing CMOS integrated circuit technology and CMOS RF technology.

FIG. 43: Schematic diagram of a monolithic CMOS-based micro-photonic and user card system showing the generic components of such a system, and utilizing CMOS integrated circuit technology and CMOS Infra Red and Si LED technology.

FIG. 44: Schematic diagram of a inductor variable capacitance diode configuration that can be realized on CMOS chip and radiate frequencies to well within the GHz range.

FIG. 45: Schematic diagram of a inductor variable avalanche based capacitance diode configuration that can be realized on CMOS chip with enhanced current levels and radiated frequencies to well within the GHz range.

FIG. 46: Cross-sectional views of dedicated structures that can be utilised for generating and propagating GHz RF laterally in (1) the CMOS over-layers and (2) at the silicon oxide interface.

### DETAILED DESCRIPTION OF THE INVENTION

According to the invention basic micro system photonic devices and Micro-Optical Electro-Mechanical Sensor (MOEMS) devices are described that can be realized in CMOS silicon. Furthermore, the definition and construction of underlying CMOS structures which will support the realization of diverse columniation, optical coupling, optical directioning and optical wave guiding in these structures are outlined. In addition specific choices regarding the wavelength that should be used to operate such devices are given.

In the following, exemplary embodiments of micro system photonic devices are described. Three categories of such micro-system design can be identified:

(i) Using CMOS Integrated circuit with integrated optical source and directional emitter and detector structures as a platform and adding some kind of mechanical structure in package form with which using the optical emissions interact;

(ii) Using CMOS Integrated circuit with integrated optical source and directional emitter and detector structures as a platform and adding some kind of optical-mechanical structure in package form with which using the optical emissions interact;

(iii) Using CMOS Integrated circuit with integrated optical source and directional emitter and detector structures as a platform and adding some kind of integrated wave guiding structure to the optical source and detector structures such that optical filtering, wave guiding of the optical radiation occurs on chip, and only a selected art of the waveguide is exposed to the environment, and intensity and phase changes are induced to the wave guided light due to interaction with the evanescent field structures of the waveguide. Hence a variety of gases and molecules and even mechanical sensing parameters can be detected with such a structure.

The first inventive concept deals with using CMOS Integrated circuit with integrated optical source and directional emitter and detector structures as a platform and adding some kind of mechanical structure in package form with which the optical emissions interact.

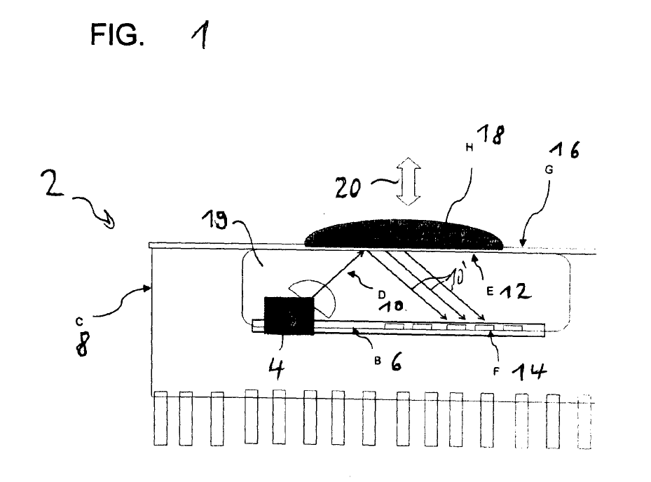

FIG. 1 illustrates the conceptual generic principles of a micro photonic system 2 which can be applied in many variations. Firstly, a silicon CMOS optical source 4 is fabricated in integrated form on a CMOS chip 6 with a substrate which is mounted inside the crevice of a CMOS package 8. Hence an over-layer structure is fabricated in integrated form or it can be added in hybrid form, on top of the CMOS chip 6 such that directional emission of the optical radiation 10 occurs. This radiation interacts with a reflecting surface 12 which reflects light back into the package crevice and onto the CMOS chip 6. A series of detector structures 14 is fabricated such that the reflected optical radiation 10′ interacts in singular form with a particular detector in globular with varying intensity with a number of detectors 14. The mechanical reflector structure can be adhered to a thin membrane 16 on the top surface of the CMOS package 8 which in turn can be adhered to a touching pad 18 or coupled mechanically to some other moving mechanical structure. A completely enclosed (dark) enclosure is such created as a cavity 19 which enables efficient detection of the reflected radiation 10′. The membrane 16 is coupled to the outside environment and can hence transfer mechanical movement in one axis 20 into difference in geometrical optical reflection onto the discrete detectors. Such a system 2 can hence detect vibration, acceleration, inertia and diverse related mechanical or motion properties as associated with the membrane. Other applications are stress and distance measurements or applications for micro-metrology through further secondary mechanical couplers. If the cavity 19 is hermetically sealed, the membrane 16 can detect also pressure and temperature. It follows that an extreme low cost and simple CMOS packaged sensor device 2 can be realized following an integrated optical source and hybrid package approach. The CMOS optical source 4, and detector 14 and processing circuitry can all be fabricated in highly integrated form while the hybrid components can be added as secondary (post) constructions in the CMOS fabrication process. The whole device 2 can be realized in extremely low and highly miniaturized and integrated format.

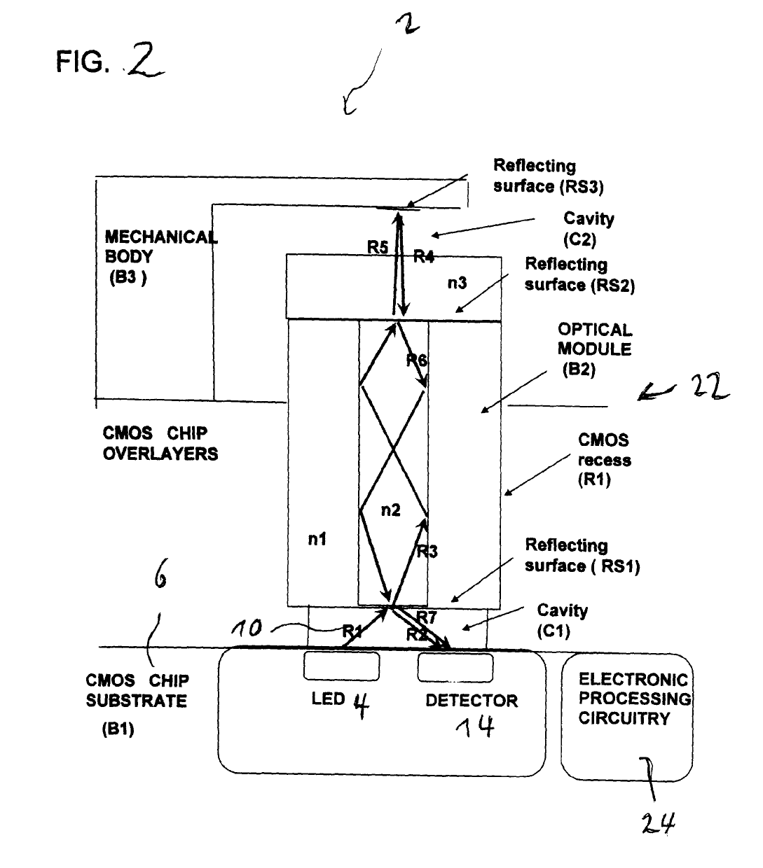

The second embodiment of a micro photonic system 2 is outlined in FIG. 2. Using CMOS Integrated circuit with the integrated optical source 4 and directional emitter and detector structures 14 as a platform and adding some kind of optical-mechanical structure 22 in package form with which using the optical emissions 10 interact. Particular in this approach is the addition of an optical module 22 that accumulates light vertically from the chip 6 and waveguide light vertically outwards from the chip surface, collimates the optical radiation where it can subsequently interacts with secondary mechanical body and reflecting surface. Light is reflected vertically backwards into the module again, and is then wave-guided back onto the chip 6 surface. By controlling the positioning of the emitters 4 and detectors 14 relative to the module 22, the optical path of the transmitting and reflective components can be separated and the reflected component can be distinctively detected. The device 2 hence creates a short vertical optical interactive space cavity region where intensity changes induced by mechanical motion of added mechanical modules or optical absorption due to gases or liquids can be detected in the vertical optical cavity.

More specifically, the system 2 includes three separate modules or bodies: a semiconductor chip module B1, an optical module or body B2 and a mechanical module or body B3, relative to each other as shown in FIG. 2. The integrated (or embedded) light emitting diode 4 emits light of a narrow bandwidth into the recess cavity C1 facilitated previously in the CMOS over layers. Rays impact on a partially reflecting surface RS1. A certain percentage intensity of these rays is reflected to the integrated (or embedded) detector 14.

Another percentage of the light is refracted into optical body B2 body and follows internal reflection paths R3 as indicated in FIG. 2. At the partially reflecting surface RS2, a percentage of the light is reflected back to the chip interface according to rays' path R6. Emitting from the optical body B2 after further refraction as, the externally reflected light interferes with the initially reflected light R2 and cause intensity change in the light reaching the detector 14. Another percentage of light at partially refracted at RS2 enters the n3 refraction index region of the optical body B2, and emits normally to this body, then travels through a second cavity C 2, is reflected back at reflecting surface RS3. A percentage of this reflected light returns back into the optical body B2 and contribute to phase contrast and intensity change at the detector 14.

Basically, the optical body B2 and the mechanical body B3 imposes phase changes and subsequent intensity changes at the detector. Both these phase changes are a high function of the physical status of the optical body and the mechanical body. If the temperature of the optical body changes, the total path length of rays R3 and rays R6 in the optical body changes and will cause a intensity change at the detector.

If the mechanical arm position changes status, the path length imposed by rays R4 and R5 will cause an intensity change in the detector 14. Shock, motion, acceleration or rotation of the device will all impose position changes of reflecting surface RS3 and results in intensity changes detected at the detector 14.

Ambient light level can also be detected in the cavity C3 (normally air) by providing a progressive stepping increase in the intensity of the LED 4 and monitoring when correct phase contrast changes are detected according to predetermined correct levels when the intensity of the rays are higher than the ambient lighting.

By extending the air gap path into the secondary cavity environment, intensity changes can be detected at the detector due to various status changes in this cavity e.g. if fluid flows introduced through the cavity C2. The arm can be appropriately modified to detect fluid flow rate. If particles of high optical absorption flow through cavity c, this will impose sharp changes in the intensity transmitted through C2 which will enable particle counts by the processing circuitry. Similarly, other properties such as absorption and fluorescence as caused by the particles can accordingly impose changes on the intensity as detected by the detector.

The signals at the detector is appropriately electronically analyzed and processed for suitable interpretation by an electronic processing circuitry 24, e.g. a micro-processor circuitry.

The device 2 dimensions and detail design of each sub module can be greatly adapted to optimize a particular physical parameter measurement. For higher temperature sensitivity, the mechanical body B3 can be omitted totally from the device 2 and the fiber section n1 and n2 of the device 2 can be extended in order to detect temperature changes at greater sensitivity. For greater sensitivity in motion and movement parameters, the mechanical section and cavity c section can be tailor designed to optimize this measurement. The device 2 should also be designed with appropriate dimensions, body and refractive indices.

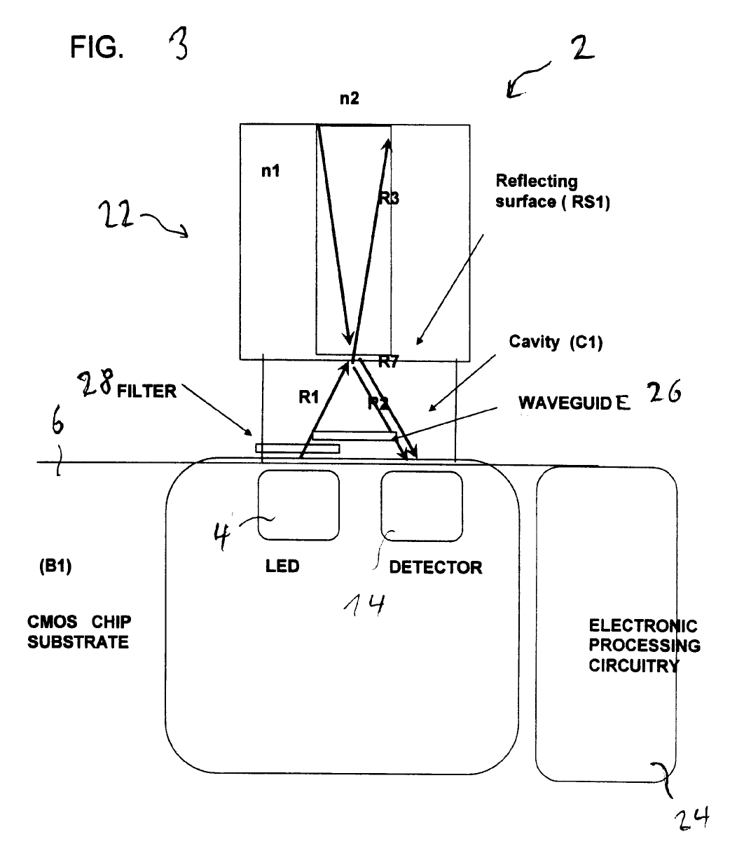

FIG. 3 shows a further embodiment indicating optional expansions of the generic system 2 in order to increase efficiency and precision of the system 2. For higher sensitivity of phase contrast a dedicated waveguide 26 can be incorporated between the source 4 and the detector 14 and a dedicated optical or diochric filter 28 can be inserted on top surface of the LED 4. The optical filter 28 will decrease the bandwidth of the impinging light increasing phase contrast sensitivity. The waveguide 26 from the source after filtered to the detector 14 area will decrease reflection loss at RS1 and subsequently also increase phase contrast detection.

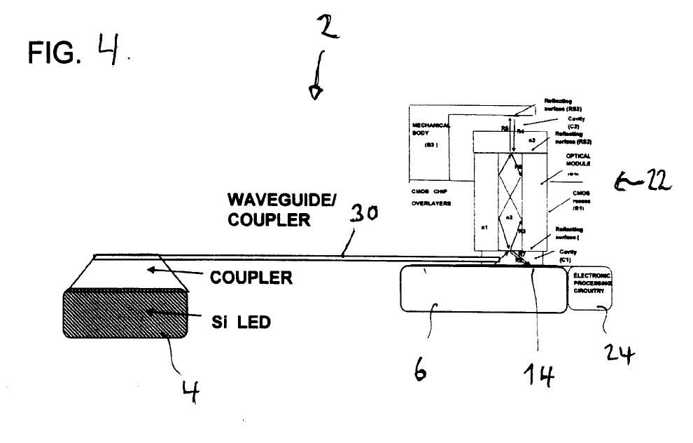

FIG. 4 gives a further example of an embodiment with an optional expansion of the generic system 2 in order to increase efficiency and precision of the system 2. For higher sensitivity of phase contrast a dedicated waveguide/coupler 30 can be incorporated between the source 4 and the injection point of the device to RS1. This configuration will separate the optical source 4 from the measurement part of the device and ensure greater sensitivity and thermal stability in the mechanical-optical measurement region, avoiding thermal effects as may be imposed by the LED source 4 operation.

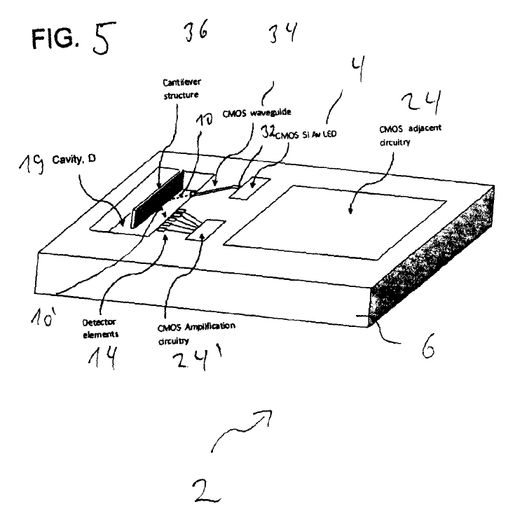

In FIG. 5 a discrete optical emission source 4, optical couplers 32 and lateral waveguide elements 34 together with receiver waveguides (not shown in FIG. 5), optical couplers (not shown in FIG. 5) and detector elements 14 are all fabricated laterally onto the same CMOS chip 6, together with optical driving and signal processing circuitry 24. The wave-guiding elements 34 appropriately confine and waveguide the optical radiation laterally on the chip 6. Appropriate lateral lens structures (not shown in FIG. 5) can be incorporated at the end of the waveguide structures in order to appropriately collimate or detect radiation 10 or 10′ at a particular angular acceptance angle of detector 14. Mechanical cantilever 36 or vibrating structures can be fabricated by employing chemical or RF post processing procedures such that a lateral mechanical structure is formed with which the optical radiation 10 as projected by the waveguides 34 can interact. Variation in the mechanical reflective surface will again induce intensity changes at the detector 14 sites which can be appropriately interpreted by the detector elements 14 and adjacent signal processing circuitry 24 after amplification by amplifiers 24′. The detection and application concepts are the same as previously described. An optical geometrical cavity 19 is formed at position D which can detect optical intensity changes as induced by optical gases, liquids or contaminant particles in such gases or liquids. In this case liquids and gases will be directed vertically through the CMOS chip 6. The advantage of this design is a further simplification of fabrication in highly monolithic form with viable post processing techniques and with a minimum of hybrid components added to the structure.

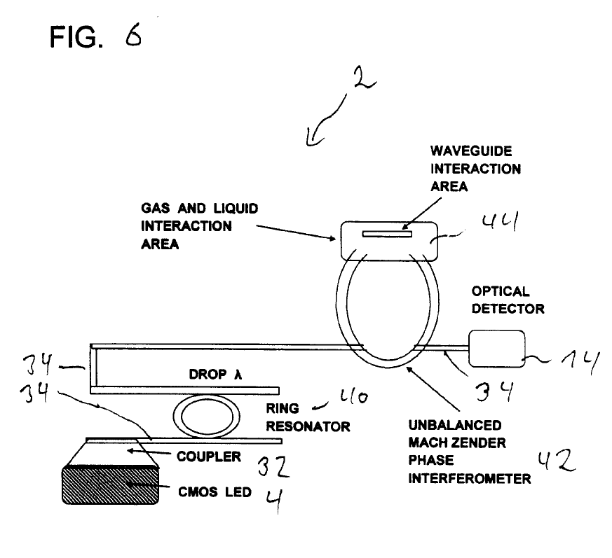

FIG. 6 describes a further monolithic integrated version of a micro photonic system 2 which can be realized with wave guiding technology on a silicon substrate. A complete integration version of the device can hence be manufactured on the device. In this design, a suitable integrated optical source 4 emits radiation 10 via the coupler 32 into the optical waveguide 34 with low optical loss for the wavelength chosen. A ring resonator 40 drops a particular wavelength into the waveguide 34 which is fed to a Mach-Zehnder 42 arrangement with one extended arm. This arm can be designed to interface with optical arms or actuators as described earlier, the reflected light returned to the Mach-Zehnder 42 filter and the phase contrast and intensity changes detected.

Important considerations are the choice of optical source 4.

The device structure and waveguides 34 are hermetically sealed enclosing all optical sources waveguides, detectors and electronic processing circuitry. A crevice 44 is etched through the passivation layers of the CMOS over-layers in order to exposes only a small section of waveguide 34 to the external environment. Here adsorption of gases or liquids will interact with the evanescent field of the waveguide 34 and induce intensity or phase changes in the one arm of the Mach-Zehnder interferometer 42. The interferometer 42 greatly increases the sensitivity of intensity and phase contrast as detected by the detector element 14 and greatly increases the sensitivity of the device 2. Appropriate micro and nanotechnology can be engineered to the waveguide in order to facilitate selective absorption of molecular species or gases and hence target selected detection of gases and liquids. The device and structure is again fabricated in highly monolithic form with minimal post processing procedures. The lateral layout CMOS compatible optical source 4, optical waveguides 34 and communication and detection structures 14 enable a highly integrated approach using only CMOS silicon processing.

From the above description, it should be clear that the performance of any micro photonic system 2 is related to the coupling or collimating of the emitted radiation 10 into either the adjacent structures on the substrate 6 or in to the cavity 19. Furthermore, radiation 10′ impinging on the detector 14 may be guided through appropriate couplers or wave-guides. In addition, structures capable of splitting beams may be necessary. These structures are referred to as means for optical transmission, which are designed such that they are fully compatible with present CMOS processing technologies. Effective coupling of radiation between the substrate 6 into a means for optical transmission will be described in the following.

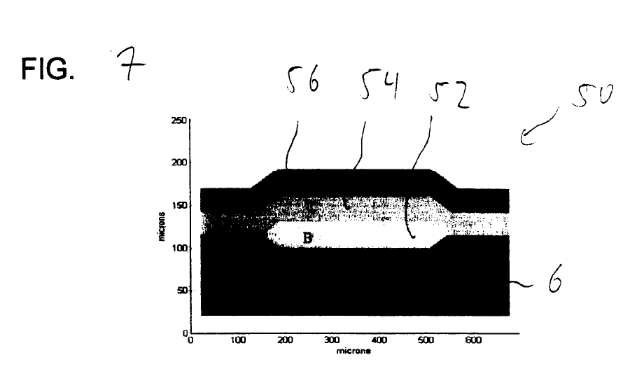

Referring now to FIG. 7, shows the means for optical transmission 50 in a typical layered structure. The different layers are the silicon base substrate 6, a native silicon dioxide layer 52 which is partially deposited on top of the substrate 6, an inter-metallic or plasma deposited oxide layer 54 which covers the silicon dioxide layer 52 and the substrate 6 and a silicon nitride or polymer layer 56 with higher refractive index than other oxide layers.

FIG. 8 shows the emitted radiation 10 in a simulation as observed when the optical source 4 is placed at the bottom of the substrate 6 and oxide layer 54 interface and a certain amount of “bending” of the overlaying plasma oxide and passivation nitride 56 was assumed, due to the absence of any metal contact layers in the structure. The optical launch angles for the rays 10 were chosen in the range of 30°-150°. The design can be implemented to include a circular nature of the centre field oxide region 52.

The analyses show clearly that light penetrates quite well vertically upwards in the structure through the field oxide layer 52, the plasma deposited layer 54 as well as the passivation silicon nitride layer 56. The result is a clear semi-isotropic radiation pattern 10 with almost 120 degrees of solid angle emission to the chip external environment. This lead to a total (external) optical emission factor approximately 0.40 of all the optical radiation as generated at the Si—SiO₂ interface 6, 52 of the source 4. This is up to twenty times higher than has been observed for any previous designs where emission factors of 0.02 to 0.04 were recorded. Some minor scattering is observed due to surface bending irregularities at the silicon nitride air interface and some absorption loss will occur in the silicon nitride layer 56 for shorter wavelength radiation.

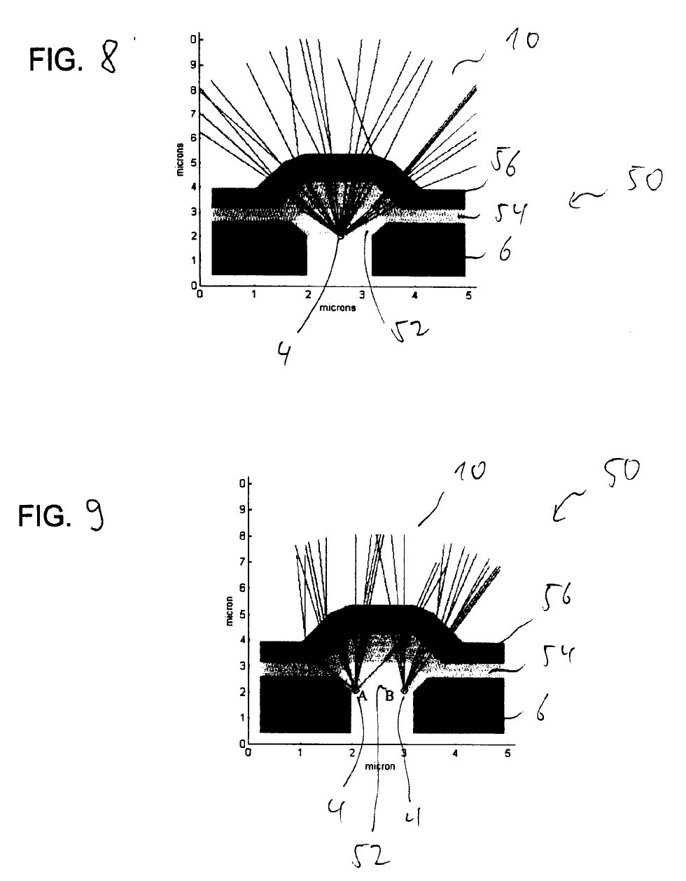

FIG. 9 demonstrates the same basic spherical silicon nitride structure as above, but the source 4 emitter positions have been shifted. When the source 4 is placed at position A, a clear focusing of almost all rays 10 emitting vertically from the means for optical transmission 50 is observed. When the source 4 is placed at position B, a clear directional emission of the radiation 10 towards a slanted 45 degree angle is observed, also with some focusing or converging of optical rays present i.e. optical focusing and directional emission of optical radiation.

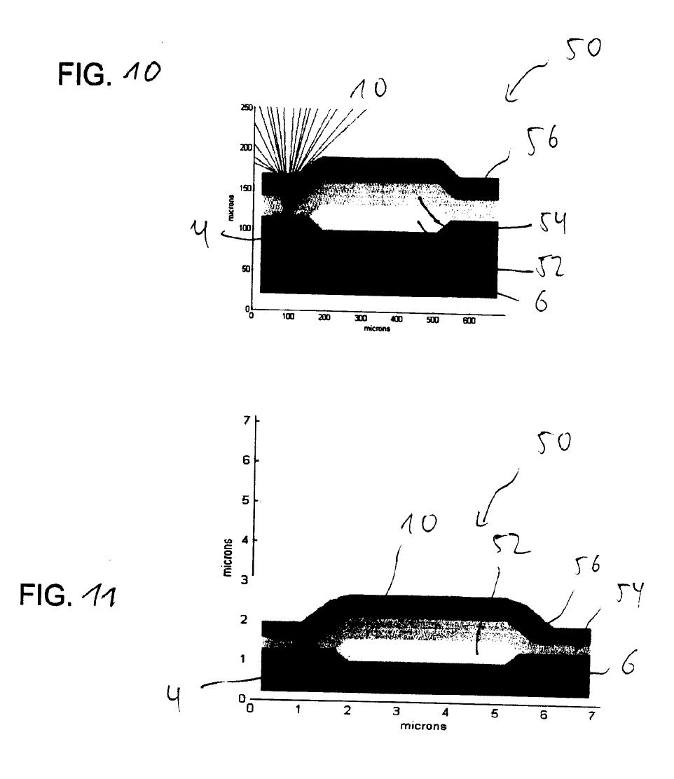

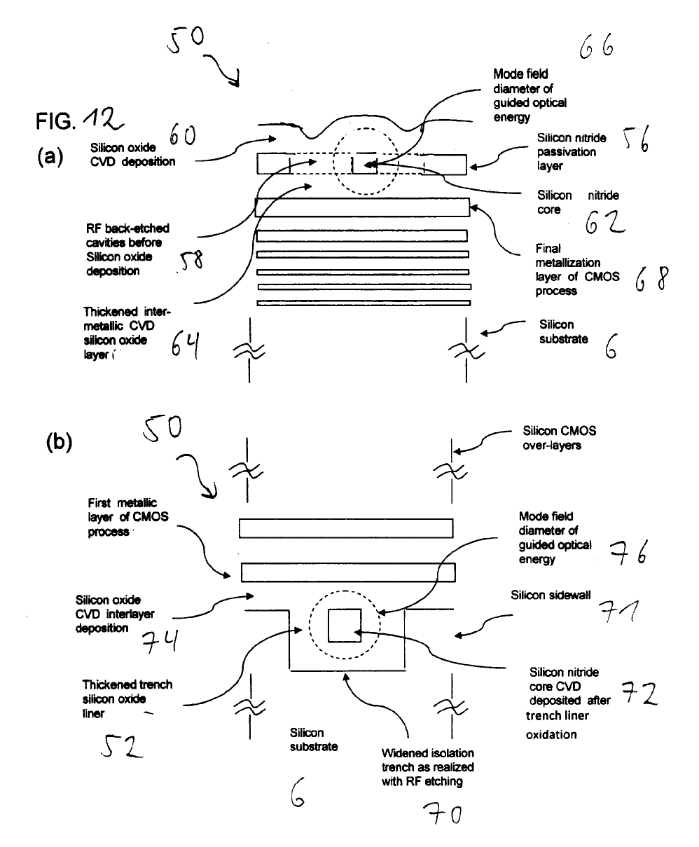

FIG. 10 demonstrates means for optical transmission 50 that can be used to create optical splitting of the optically radiated power in more or less equal percentages in two different paths. In this case a 0.3 micron field oxide layer 52 and 1 micron silicon passivation and plasma deposited layers were assumed as commonly encountered in 0.35 micron CMOS technology. One portion of the radiation 10 emitted out of the structure into air, and the other radiation 10 was emitted laterally into the silicon nitride layer 56. Optical splitters of this kind have wide and diverse applications in MOEMS applications and can be used to generate interference and phase contrast in certain applications as described above.

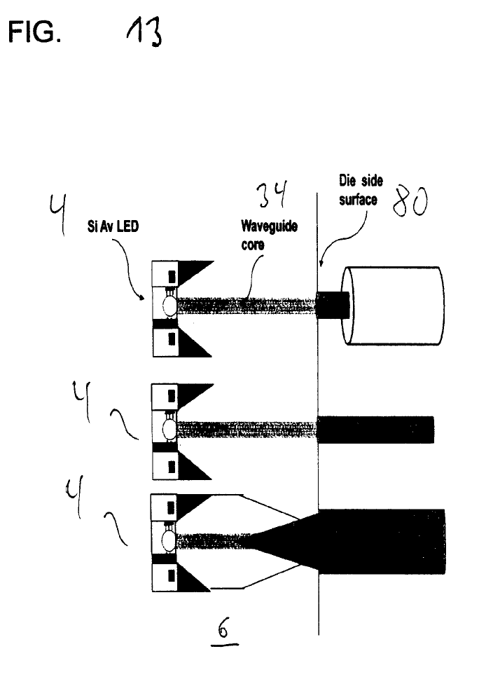

FIG. 11 demonstrates optimized lateral wave-guiding longitudinally along the silicon nitride layer 56 for a very high proportion of the totally emitted Si LED 4 radiation. The plasma oxide layer 54 thickness has been reduced locally and the optical emission point in the generated structure was positioned near the “bird peak” point in the silicon oxide layer 54. Analysis shows that initial rays launch angles ranging from 34°-76° couple effectively into the silicon nitride layer 56. Due to the lower refractive indexes of both the plasma and field oxide below the layer and the refractive index of air above the layer, the radiation 10 can be quite effectively guided along the silicon nitride layer 56.

A very important outcome of this analysis is that silicon nitride and silicon oxi-nitride is essentially transparent for radiation for radiation higher than 600 nm. This is substantially lower than the absorption edge of silicon which lies at approximately 850-950 nm. Silicon nitride therefore offers itself as a most suitable candidate for generating electro-optic and waveguide structures in CMOS integrated circuitry.

Since Silicon nitride and oxi-nitride offer low loss wave guided transmission above 650 nm and since silicon detectors are decreasing in detection efficiency above 850 nm, it is proposed to utilize a wavelength of operation between 700-800 nm. This will allow the design and construction of so called all silicon CMOS based detector modules with only a minimum of hybrid components added to the transmitter module. The same CMOS wave guiding technology can be used for both transmitter and receiver modules.

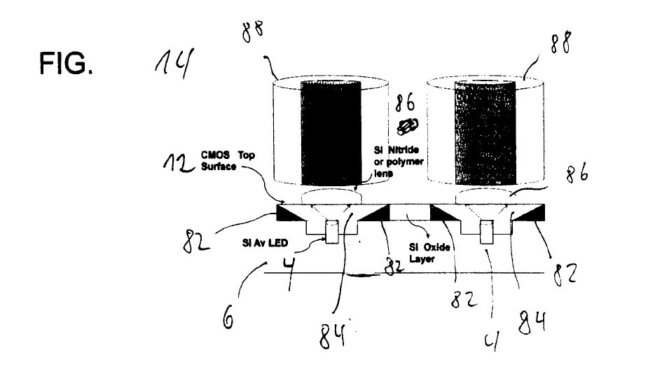

FIG. 12 (a) shows a further embodiment of a means for optical transmission 50 in a cross-sectional view. The means for optical transmission 50 is a waveguide structure that can be realized in the CMOS over-layers 68 on the substrate 6. This structure can be used as the waveguide 34 of the previous embodiments of FIGS. 1 to 6. Sections 58 are etched away in the normal final silicon nitride passivation layer 56 that is used in the CMOS process. This is followed by further silicon CVD plasma deposition of silicon oxide 60. A centre silicon nitride core strip 62 forms the guiding cross section for a travelling optical wave 10 along the core structure. If the dimensions are appropriately chosen, a percentage of the electric field at 66 will propagate in the surrounding silicon oxide region 64 which forms the “cladding” of the waveguide. The core structure can also be processed circular through appropriate refined processing procedures. The exact dimensions determine the nature of the wave guiding, being single mode or multimode and the energy being transferred mainly in the core or the cladding, as well the design capabilities of other wave guiding components.

FIG. 12 (b) shows a cross-sectional view of a waveguide structure that can be realized in the CMOS silicon bulk using trench etching and secondary deposition techniques. The normally used trench isolation trench 70 is widened in substrate 6. The native silicon field oxide layer 52 is thickened to form appropriate side walls 71 in the trench 70. A thin strip of silicon nitride 72 is then deposited in the centre part of the trench 70 and finally covered up with a wider strip of CVD deposited silicon oxide 74. Appropriate planarization is applied in order not to affect the further CMOS processing procedures. The core 72 can be realized in rectangular or circular cross-section form in a cladding structure of silicon oxide 52 or other material. The exact dimensions determine the nature of the wave guiding, being single mode or multimode and the energy being transferred mainly in the core or the cladding, as well the design capabilities of other wave guiding components. The mode field diameter is schematically indicated by reference numeral 76. The first metal layer 78 and further CMOS layers 79 are also indicated in FIG. 12 (b).

In FIG. 12, specific CMOS based waveguide structures operating at 750 nm wavelength using CMOS materials and processing parameters have been developed which show that effective multimode, as well as single mode wave-guiding can be achieved in CMOS structures with channel strips of 0.2-0.6 micron wide, embedded in silicon oxide of up to 1.5 micron diameter. These structures can either be fabricated in the over layers of the CMOS IC structure using above 0.35 micron technology, or in the isolation trenches as are available in below 0.35 micron CMOS technology.

With further simulations of the means for optical transmission 50 as described above with respect to FIGS. 12 (a) and (b), it was found that a clear multi-mode type of propagation is achieved with almost zero loss as function of distance over a length of up to 20 micron. Multi-mode propagation in CMOS micro systems has the advantage of allowing both a large acceptance angle for coupling of the optical radiation from the silicon LED 4 into the waveguide 34 as well as for emission of light 10 out of the wave guide at the end of the waveguide 34.

Furthermore, a low loss characteristic of 0.65 dB·cm⁻¹ is predicted. Correspondingly a value of approximately 200 GHz-cm could be derived for the bandwidth-length product from the calculated effective refractive index values and predicted dispersion values. The utilization of a short wavelength and high index refractive index difference between core and cladding (1 micron in diameter) suggests that high level of micro bending can be achieved. Also, since CMOS technology offers the realization of many different over layer structures on top of each other, it implies that coupling of optical energy can easily be achieved between waveguides and optical sources near to the silicon over-layer interface to layers higher up in the structure. This imply transferring of optical radiation from substrate level to many different waveguide layers higher up in the structure, as well as cross coupling of radiation between such structures.

The far field patterns of the optical propagation as emitted from the end of the waveguides can easily be manipulated by either utilizing adiabatic expansion techniques or by reducing the core size near the end of the waveguide and allowing the mode field diameter to spread wider into the silicon oxide cladding. This could allow effective coupling of the optical radiation into adjacently placed or edge-placed optical fibers.

A simple two dimensional silicon nitride lens type structures can be achieved and placed at the end of the waveguides. Such designs can indeed be utilized to obtain two and three dimensional control of the optical emission at distances up to 10 micron away from the edge of the waveguide.

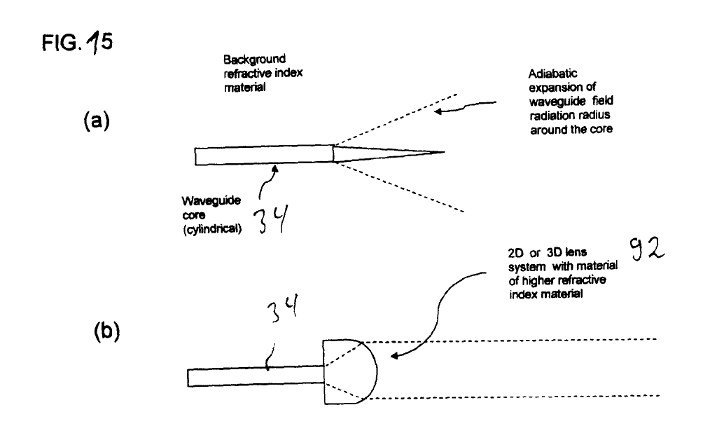

In a further approach, optical coupling is achieved by means of lateral wave guiding through waveguides 32 to the one side surfaces 80 of the die forming substrate 6. FIG. 13 illustrates this schematically. The lateral optical coupling from the optical source 4 can be engineered as high as 0.8 as demonstrated in the previous section. The optical radiation can be converted from multi-mode propagation mode to single mode propagation mode by means of appropriate waveguide based mode converters. The existing of radiation in single mode at the side surface ensures that it is highly calumniated. This enables a coupling efficiency of very near to 1.0 at the side surface. In total, an optical coupling efficiency of up to 0.8 can be achieved. This is much higher than achievable with vertical type of coupling technology.

In a further approach, use is made of silicon oxide and silicon nitride as well as trench technology as outlined in FIG. 12 (b) in order to increase the vertical outwards radial propagation. FIG. 14 schematically illustrates the concepts. By placing the thin section of silicon 82 adjacent to two semi-circular trenches 84, the optical outwards radiation is increased from a solid angle of emission within the silicon is increased from about 17 degrees to almost 60 degrees. Filling up the trenches 84 with SiO₂ (at 86) and then placing of thin layer of Silicon nitride layer 88 furthermore increases the critical emission angle from the silicon from 17 degrees to 37 degrees. The thin layer of silicon nitride 86 can furthermore be appropriately shaped with post processing RF etching techniques as a lens such that it can direct all emitted light vertically upwards. It is estimated that a total optical coupling efficiency from silicon to a fibre 88 of up to 0.4 can be achieved with this technology.

An important part of the invention described here is that silicon nitride is effectively transparent for the longer wavelengths above 600 nm. Special layers utilizing silicon oxi-nitride (SiOₓNₓ) compositions offer transparency at slightly lower wavelengths. In both cases the wave guided or transmitted radiation 10 is still much lower than the absorption edge wavelength for Si detectors (approximately 950 nm). Accordingly, both silicon nitride and Si oxi-nitride offer good possibilities for transmitting radiation at low loss in the wavelength regime 650-850 nm. Both Si Oₓ N_{y} and Siₓ N_{y} offers high refractive index of 1.6-1.95 and 2.2-2.4 respectively, against a background of available SiO₂ as cladding or background refractive index layers in CMOS silicon.

In general, it follows, that combining CMOS compatible sources effectively with on-chip dedicated waveguide technology, couplers or lenses as means for optical transmission 50 offer major advantageous, regarding coupling efficiencies, increasing optical link budgets, increasing bit error rates in high speed communication, and coupling with the external environment.

In the following further embodiments of the means for optical transmission 50 are described.

In FIG. 15 shows plan views of integrated waveguides 34 that can be realized in CMOS technology.

FIG. 15 (a) shows a plan view of a waveguide structure 34 where tapering of the core of the fibre is used to cause adiabatic expansion of the field around the core. Such a configuration can either be used to ensure better coupling of radiation into an adjacent structure or also facilitate a diverging propagation nature of radiation when it exits the waveguide at an abrupt placed cross-sectional surface. The exiting radiation pattern 10 should be interpreted in three dimensions as conical shape in nature.

FIG. 15(b) shows a design where a lens type structure 92 of higher refractive index has been added to a wave guide 34 in order to cause adiabatic expansion of radiation into the lens followed by refraction into a well columniated beam upon exiting the lens structure. The exiting radiation pattern should be interpreted in three dimensions as cylindrical shape in nature.

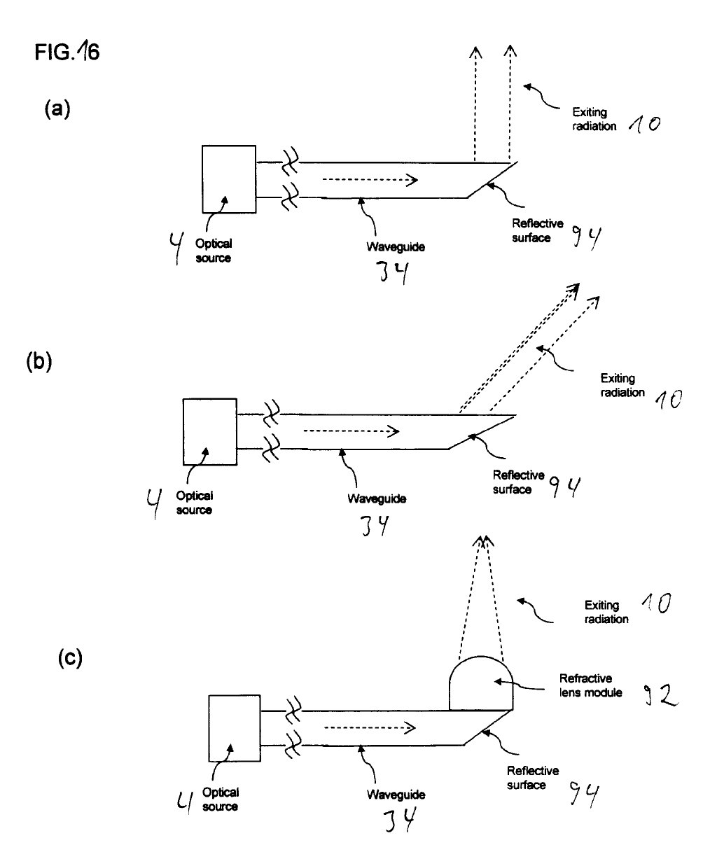

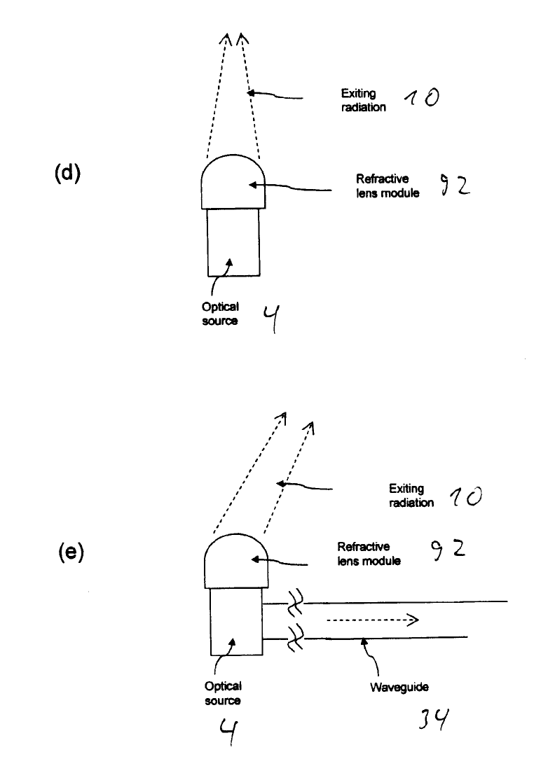

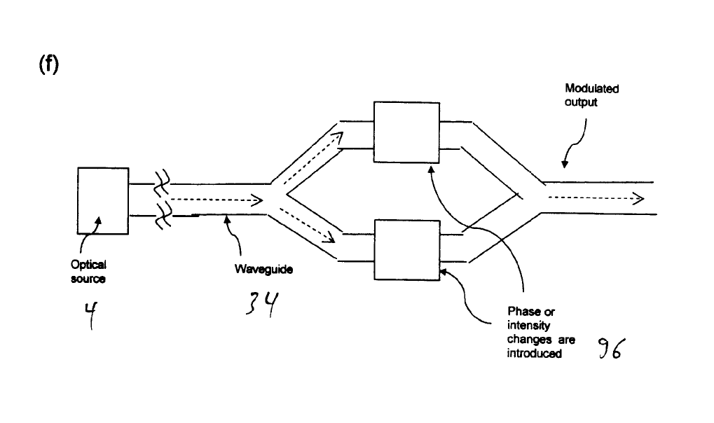

FIG. 16 shows some further combinations of combining optical sources 4, waveguides 34 and reflecting mirrors 94 and refractive lens modules 92 on a silicon platform, which builds on the previous waveguide concepts as described and which is all within the scope of the invention.

In FIG. 16 (a) an optical source 4 is combined with an integrated waveguide 34 and a reflecting mirror 94. The coupling of the optical source 4 with the waveguide 34 ensures a very coupling efficiency of optical radiation as generated by the optical source 4 into the waveguide 34. In this particular case the optical radiation is reflected vertically up, with 45 degrees, so as to exit the silicon platforms normally as radiation 10.

In FIG. 16 (b) an optical source 4 is combined with an integrated waveguide 34 and a reflecting mirror 94. In this particular case the optical radiation 10 is reflected vertically up, with an angle of 60 degrees, so as to exit the silicon platforms at a slanted angle.

In FIG. 16 (c), a similar structure is used but on top of the reflective mirror 94, a refracting lens 92 is provided such as to focus the emitted light 10 into a focal point some distance away from the silicon platform.

In FIG. 16 (d), a refracting lens structure 92 is provided on top of the optical source 4 such that focused optical radiation 10 emits vertically above the silicon platform above the optical source 4.

In FIG. 16 (e), a combination of the previous structure as in FIG. 16 (e) is used in combination with a lateral waveguide 34, such that optical radiation is split into two paths, one vertically up from the silicon platform and one laterally along the silicon platform in wave guide 34. This combination is useful where a reference wave front is required with regard to intensity and/or phase in certain applications.

FIG. 16 (f) shows integrated waveguide structures involving the splitting of optical radiation in waveguides 34 on the silicon platform in the wavelength regime 450-850 nm according to the conventional Mach Zehnder configurations as described in FIG. 6, and creating either intensity or phase modulation 96 at the output as a result of electro-optic or charge injection effects in one of the arms (or both) of the configuration.

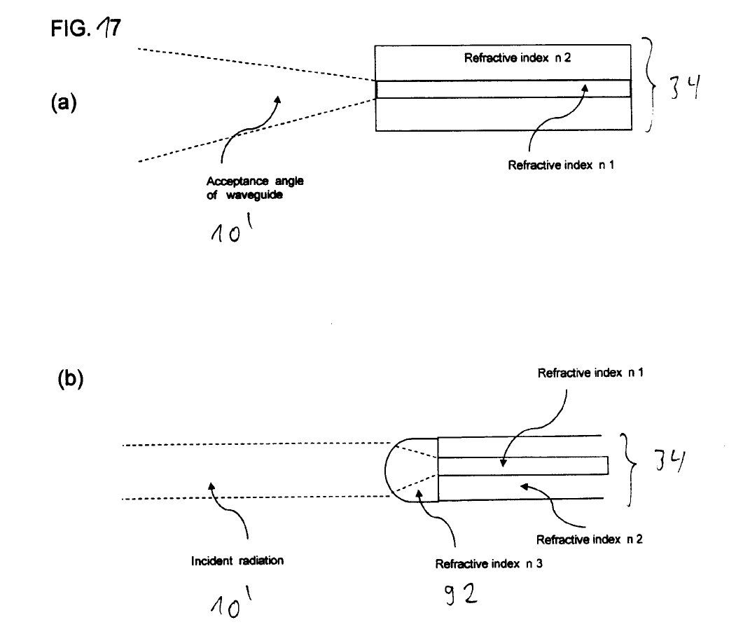

FIG. 17 (a) correspondingly shows plan view designs of waveguide structures which enables light 10′ in a certain acceptance angle only to enter the core of the waveguide. Typically such a structure can be realized at the edge of the CMOS chip in order to ensure a three dimensional cone of incident radiation to enter the waveguide on the chip.

FIG. 17 (b) correspondingly shows plan view designs of waveguide structure with a higher refractive lens 92 type structure place at the front end of a wave guide 34 such that only highly calumniated light of a very low acceptance angle enter the core of the waveguide. Typically such a structure can be realized at the edge of the CMOS chip in order to ensure a three dimensional cone of incident radiation to enter the waveguide on the chip.

It can be appreciated that similar configurations can be realized with utilizing integrated forms of integrated waveguides, reflective mirrors, but with the optical source 4 elements being replaced with detector elements 14 and the configuration such generated being utilised as receiver modules.

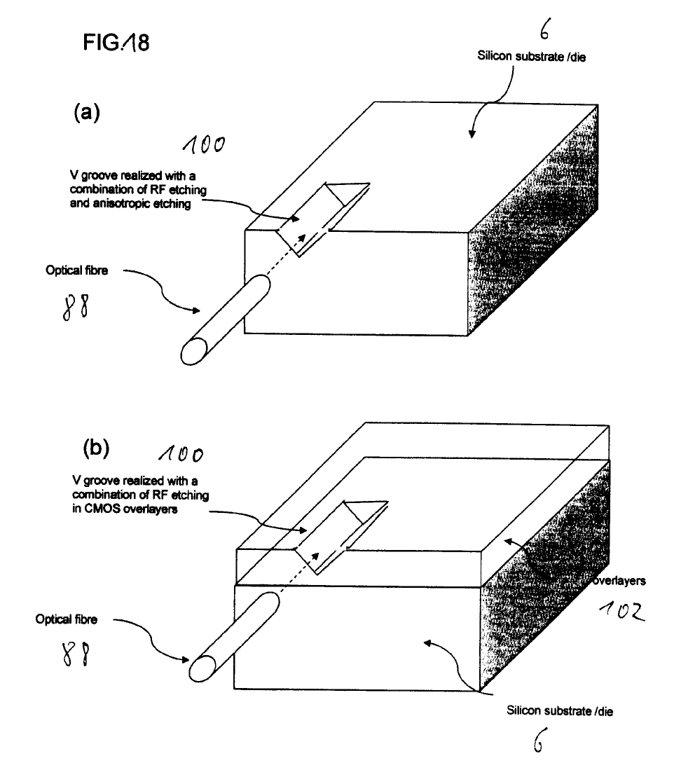

FIG. 18 shows the possible mounting of an optical fibre 88 to the edge of a CMOS die by using a V-groove configuration. The V-groove 100 can be processed by using wet or RF etching. By varying the depth of the V-groove the optical fibre core can be either be aligned with a trench waveguide core or an over-layer waveguide core as shown in FIGS. 12 (a) and (b). The over-layers are indicated by reference numeral 102.

The above technologies enable diverse applications at a chip level in order to generate specific micro-photonic systems on a silicon platform as shown in the following figures.

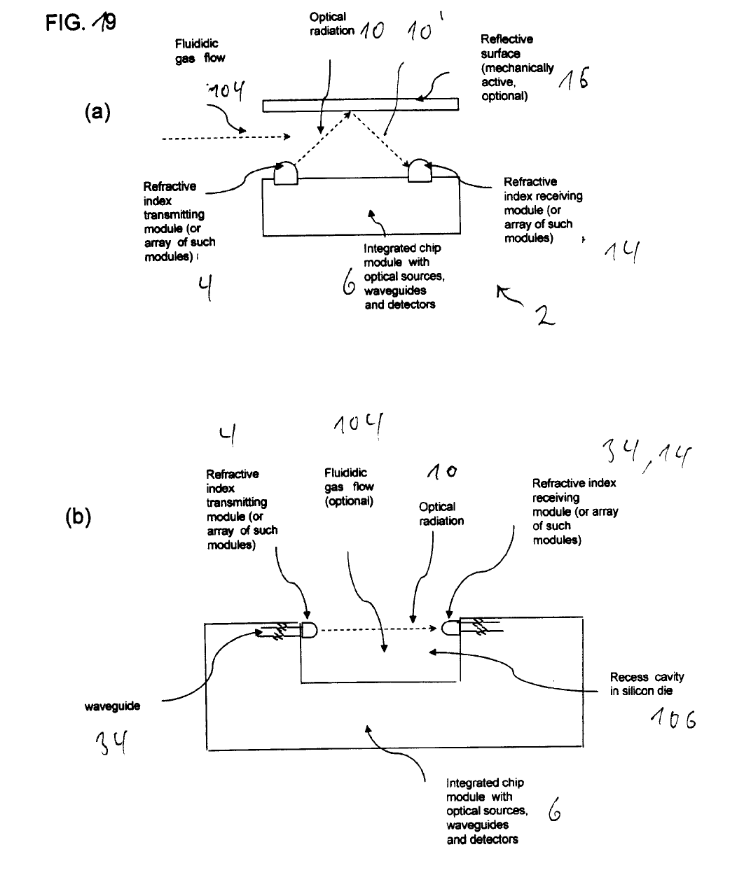

In FIG. 19 (a), optical radiation 10 is transmitted at a slanted angle from a silicon platform, such that it interacts with a reflective surface 16 some distance away from the silicon platform 6. The reflected light 10′ is detected by a single detector element or an array of detector elements 14. The reflective element/module could be of a cantilever type, it could be free standing, or either coupled to the silicon platform or some external environment component. The emission and detector modules can be of any of the integrated optical source waveguide and refractor lens modules. If a fluidic flow of gas or liquid or particles or globules at 104 is transferred in the optical paths between the silicon platform 6 and the reflecting mirror 16, the optical detected signal will be modulated and information of the fluid can be extracted. These could involve absorption analyses, or rate of absorption change or absorption pulsation which can reveal content about composition, flow rate or other physical parameters as associated with the fluid. Similarly, the reflective surface element 16 could be mechanically active and in a state of motion, vibration or constant defection. All these modes could reveal information about vibration, motion, acceleration, rotation, of the silicon platforms or chip.

In FIG. 19 (b), light is transmitted from integrated waveguide elements through a recess cavity 106 in the silicon platform, such that it interacts with an integrated detector and waveguide elements on the opposing side of the recess cavity. The transmitted light is detected by a single detector element or an array of detector elements 14. If a fluidic flow of gas or liquid or particles or globules is transferred in the optical paths in the recess cavity, the optical detected signal will be modulated and information of the fluid can be extracted. These could involve absorption analyses, or rate of absorption change or absorption pulsation which can reveal content about composition, flow rate or other physical parameters as associated with the fluid.

In FIG. 19 (c), light is transmitted from integrated waveguide elements through a recess cavity in the silicon platform, such that it interacts with an integrated detector and waveguide elements on the opposing side of the recess structure. In this case the light 10 is focused by transmitting refractor lenses as described earlier in FIG. 16 such that the transmitted light is detected by a single detector element or an array of detector elements 14. If a fluidic flow 104 of gas or liquid or particles or globules is transferred in the optical paths in the recess cavity, the optical detected signal will be modulated and information of the fluid can be extracted. These could involve absorption analyses, or rate of absorption change or absorption pulsation which can reveal content about composition, flow rate or other physical parameters as associated with the fluid. Because of the focused nature of the light at the centre of the recess cavity 106, the modulation sensitivity will be increased, such that flow rate or particle, or globule counts can be increased.

In FIG. 19 (d), light 10 is transmitted from integrated waveguide elements through a recess cavity in the silicon platform, such that it interacts with a mechanical reflective module in the centre of the recess 106, such that reflected light 10′ interacts with an integrated detector 14 and waveguide elements 4 on the same side of the recess structure. Similarly, the reflective surface element/module can be mechanically active and in a state of motion, vibration or constant defection. All these modes could reveal information about vibration, motion, acceleration, rotation, of the silicon platforms or chip 6. The centre mechanical module can be of cantilever type with its rear side mounted to the rear sidewall of the recess structure of the silicon platform.

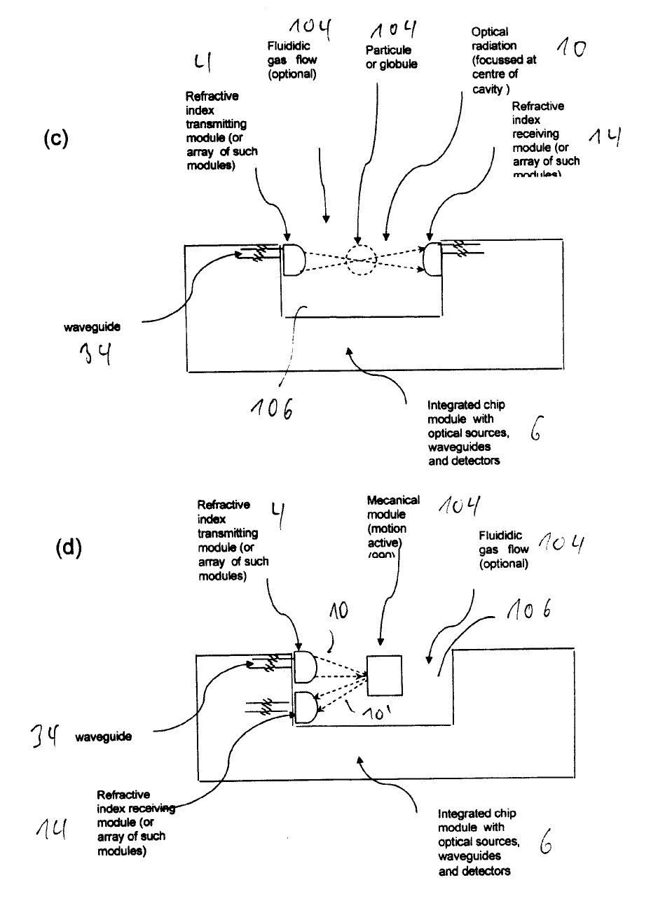

FIGS. 20 (a) and (b) respectively shows a plan and cross-sectional views of an integrated waveguide structure 34 and micro-photonic module that can detect and analyze the wavelength of incident optical radiation 10. Optical radiation is received from medium 1 at a certain incident angle and acceptance angle, it is colluminated into a integrated waveguide element 34 with a thin core structure and a wide background lower index structure, such that the optical radiation is primarily guided outside the core of waveguide in the background/cladding structure. The optical radiation is then transferred to an optical module/medium 110 with refractive index n3 of different refractive index of distinctive planar shape as indicated in FIG. 20 (a). The radiation in the refractive index n2 medium hits the refracting medium n3 interface with at a slanted incidence angle, such that the optical radiation is refracted in medium 3 and bends in propagation direction as a function of wavelength. Lower wavelengths will be least deflected, while shorter wavelength radiation will be higher defected. Each wavelength optical radiation will follow a different optical path in medium 3. A row of optical detector elements 14 which can again be of integrated waveguide nature as outlined earlier in FIG. 17, can detect each radiation separately. The resulting electronic signals can then be processed and interpreted by appropriate signal processing circuitry in the silicon platform.

In the following, a photonic micro-system 2 using either low cost monolithic integrated or hybrid manufacturing, in which a low cost and efficient optical communication, is described. The photonic micro-system 2 can be composed utilizing hybridly mounted organic light emitting devices (OLEDs) as optical sources 4 that operate in the 650-850 nm wavelength regime technology, integrated waveguide technology as outlined above and standard silicon based detectors. OLEDs have been developed that emit wavelengths at very high efficiency at green, orange or red emission wavelengths. These OLEDs can be integrated with relative ease into CMOS structures or added hybridly as a post-processing procedures to the CMOS fabrication process.

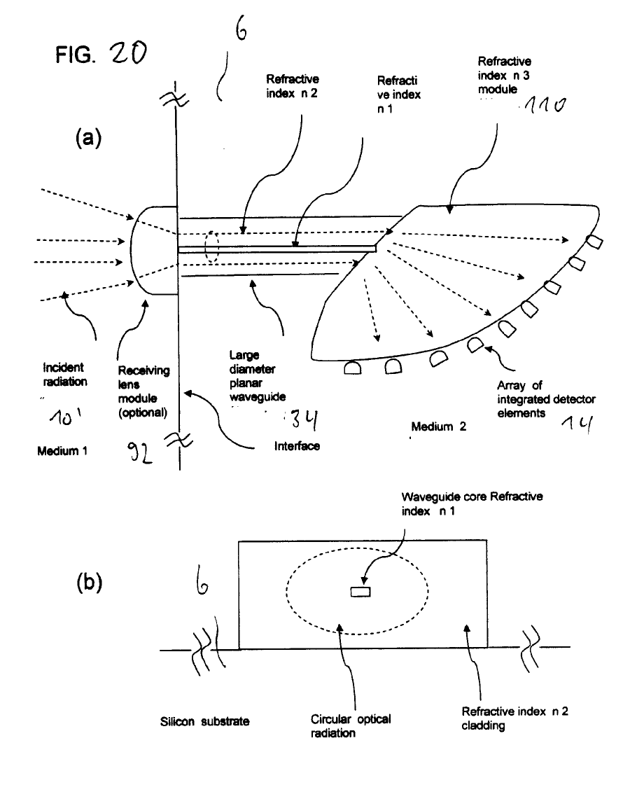

FIG. 21 (a) shows schematic plan view representation of a proposed primarily CMOS based optical transmitter chip 116, comprising of base platform 6, in this case a silicon CMOS technology die, an optical source 4, waveguide based modulator 34, a modulator 118 a waveguide biased optical radiation collimator 120, as well as driving circuitry 122, 124 and 126 for the source 4, the modulator 118 and the collimator 120 which are all designed and fabricated on a conventional Silicon die using CMOS technology.

The optical source 4 is of integrated Si OLED nature providing sufficient light to be guided along the lateral waveguide structure 34. The integrated CMOS waveguide structure 34 closely interfaces with the optical source 4. Mounted in the waveguide structure is the integrated modulator element 118. This element can use integrated waveguide modulator technology utilizing the electro-optic or charge injection effect as modulation means and utilizing Si CMOS technology, operating in the wavelength regime 650-850 nm. The use of a waveguide based modulator 118 offers extreme low capacitance and driving current, thus enabling very high modulation frequencies of the optical radiation at reasonable or very high modulation depths. The optical source 4 operates in continuous wave mode, which offers high emission and thermal stability. At the end of the integrated waveguide circuitry is facilitated an optical collimator control waveguide circuitry 126 which is used to control the columniation or divergence of the emitted optical radiation 10 from the chip. This device can utilize a combination of structural shaping of the waveguide in order to obtain certain ray bending effects and the electrostatic modulation through the electro-optic effect or the charge injection effect, or it can also operate purely on structural configuration with no electro-optic intervention. In the current embodiment of the invention silicon CMOS technology were used as base technology.

FIG. 21 (b) shows schematic plan view representation of a proposed primarily CMOS based optical receiver chip 128, comprising of base platform 6, in this case a silicon CMOS technology die, an waveguide 34 biased optical radiation collimator 130, a waveguide based de-modulator 132, an optical detector 14, an optical acceptance angle controller 134, as well as amplification circuitry 136, signal processing circuitry 138, which are all designed and fabricated on a conventional Silicon die using CMOS technology, CMOS integrated waveguide structures as outlined above, as well as integrated Silicon detector structures. The optical detector chip 128 can be of compound semiconductor type ensuring high electrical to optical conversion efficiency, and can be recess mounted and conductive epoxy pasted onto the CMOS die. The CMOS die also comprise an integrated CMOS waveguide structure 34 which closely interfaces with the hybrid optical acceptance angle controller 134. Mounted in the waveguide structure is the optical de-modulator element 132. This element can be either also recess mounted using hybrid technology or it can use integrated waveguide modulator technology utilizing the electro-optic or charge injection effect as modulation means and utilising Si CMOS technology.

FIG. 22 shows an embodiment, where an optical communication system is composed of two CMOS base die modules (one transmitter and one receiver), utilizing hybrid and integrated CMOS waveguide technology for the wavelength range 650-850 nm, integrated CMOS compatible optical modulators 118, and one hybridly added optical source module 140 that is added to the transmitter die CMOS module on special platforms or recessed cavities through pick and place technology. This approach enable elegant two chip data and other optical communication systems using mostly standard CMOS technology with a minimum of complex III-V —Si integration, or Si—Ge or SOI technology added to the CMOS processing procedures and secondary bonding technology. The hybrid modules are only added after the CMOS process through post processing procedures. Only one component in the form of one optical source 140 is added hybridly to the system. The optical modulator element can also be hybridly added through post processing and bonding techniques, should it yield higher modulation efficiency.

Diverse other applications of the system is also possible utilsing a combination of the above technologies, for example the realization of a range of diverse electro-optical, mechanical-electro-optical, chemical-optical and nano-structured based sensors, all highly integrated on single CMOS die chip modules.

Since Silicon nitride and oxi-nitride offer low loss wave guided transmission above 650 nm and since silicon detectors are decreasing in detection efficiency above 850 nm, it is proposed to utilize a wavelength of operation between 700-800 nm. In the communication and data transfer field, the combination of using a OLED that operate in CW mode in combination with a CMOS waveguide and CMOS waveguide modulator at submicron wavelengths seems particularly feasible. Because of the low driving charges as associated with the CMOS modulators, extremely high modulation speeds of up to 100 Gbps can be achieved. It is expected that high enough modulation depths may be achieved with this modulator technologies.

In FIG. 23, one application is to design a chip to multi-chip free space optical communication system as in FIG. 21(a). In this case a diverging exiting radiation pattern is chosen at the transmitting chip while columniation incident radiation patterns are designed for receiving chips.

FIG. 23 (b) illustrates a free space single chip to single chip optical communication system. In this case a highly calumniated radiation design is chosen for both the transmitting and receiving chip.

FIG. 23 (c) illustrates a chip-to-optical fibre to single chip optical communication system. In this case a combination of V groove as well as adiabatic field expansion techniques are used in order to ensure a very high coupling efficiency from chip to fibre as well as from fibre-to-chip.

In the current embodiment of the invention, silicon CMOS technologies were used as base technology. For those skilled in the art, it can be appreciated that Silicon on Insulator (SOI) technology or Silicon Germanium (Si—Ge) can also be used as base technology in order to realize the invention. The utilisation of these technologies are considered to be all within the scope of the current invention of realizing a hybrid waveguide and chip based optical communication system. Silicon on Insulator (SOI) technology may offer certain advantages with the realization of waveguide technology, while the utilisation of Si—Ge technology can enhance the speed capabilities of the modulator driving and signal processing circuitry.

The utilization of hybrid combination of optical source at 750-850 nm, CMOS based waveguide technology and conventional Silicon detector technology enable a very low cost, though highly efficient realization of such optical communication and micro-photonic systems.

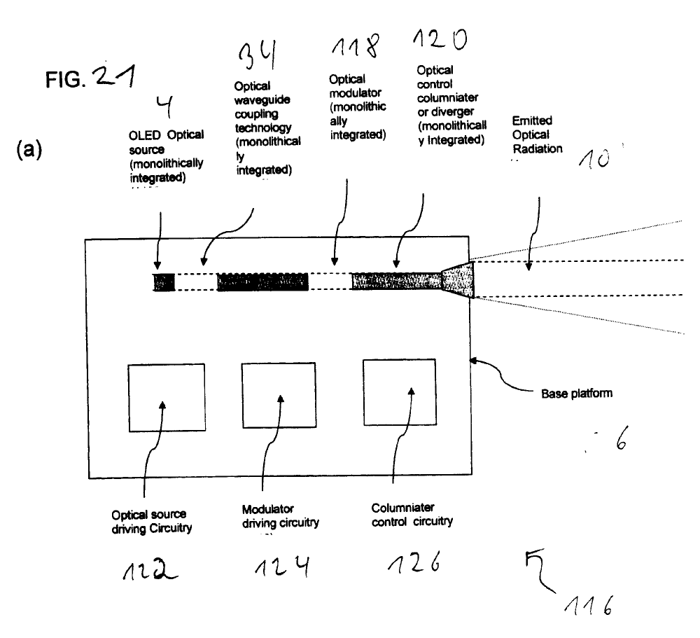

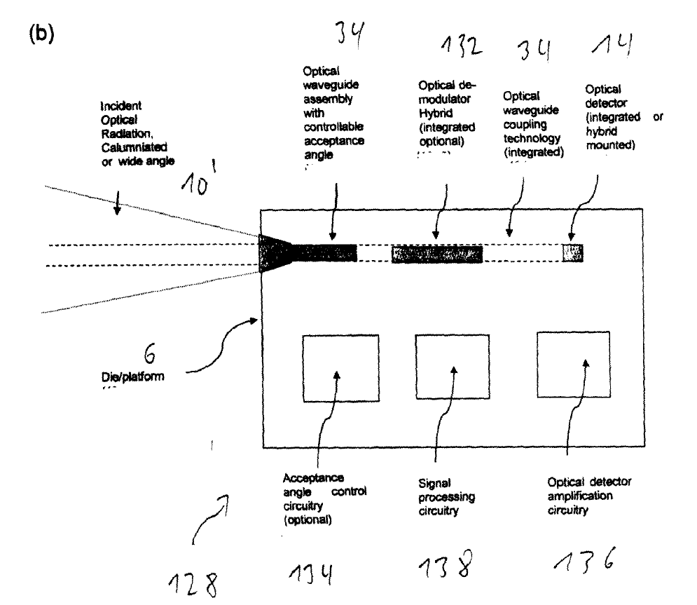

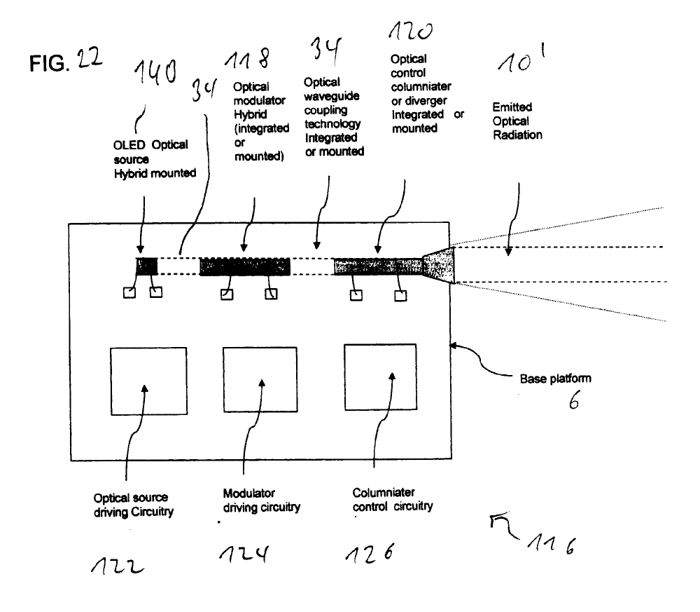

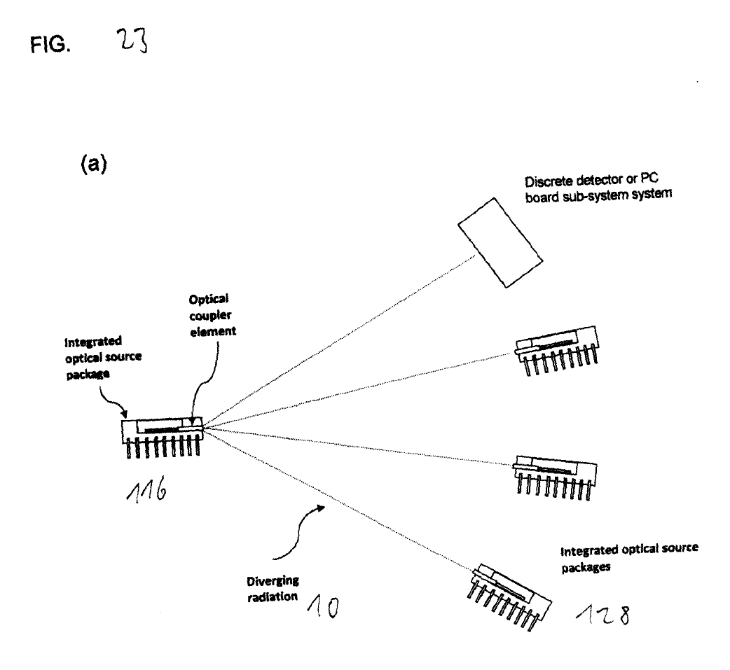

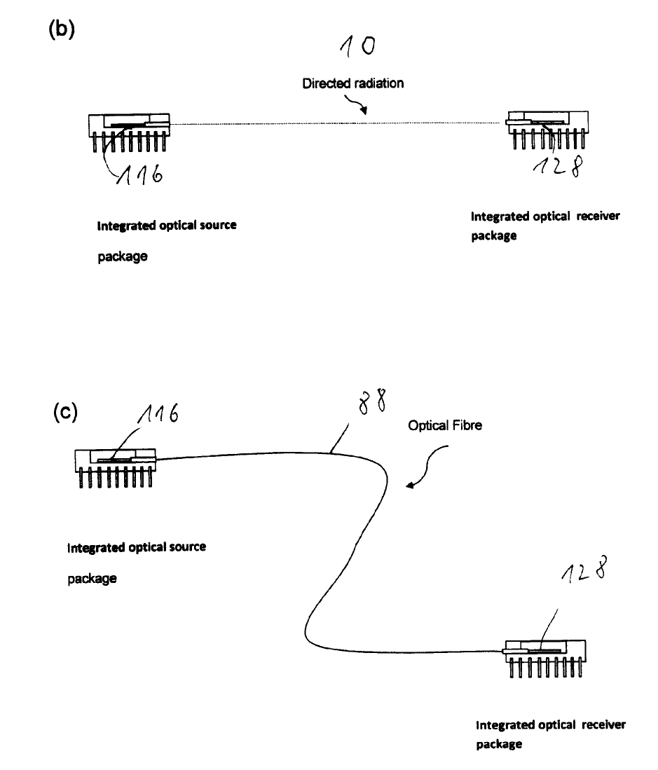

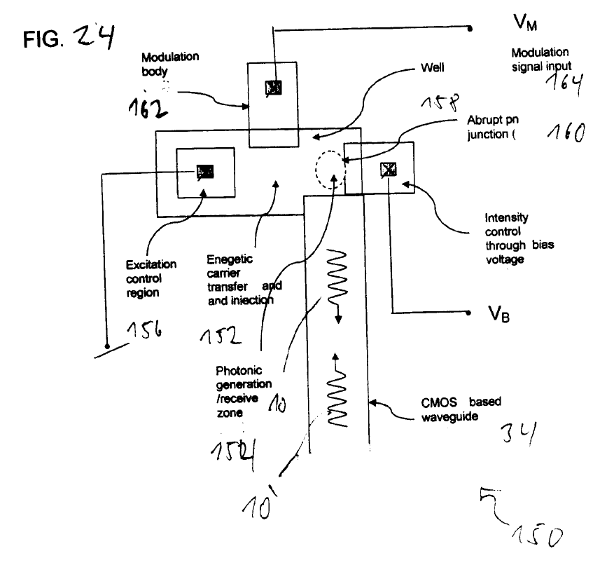

FIG. 24 shows a plan schematic diagram of a proposed CMOS waveguide based signal transmit and receive module 150. The module can convert electrical input signals to optical signals 10 that are transmitted by the CMOS waveguide 34. Similarly, the module 150 can convert signals that arrive by waveguide to electrical signals by means of photonic absorption processes in a silicon-well. The module is optimised to operate with reverse bias avalanche technology at 450-650 nm wave length. Photonic radiation as received from the waveguide 34 impinges on the module 150 being fabricated from CMOS technology and utilising CMOS technology components. Transmit and receive module 150 includes a charge carrier excitation region 156, a charge carrier transfer region 152 and a photonic generation region 154. Supply voltages can control the intensity of the photonic generation 10, the nature of the excitation and photonic generation as well as the modulation of the photonic generation. The module also consist a well region 158 which contains absorption material for the generated photonic radiation or at another wavelength such that when radiation 10′ is impinging on the well as arrived through the waveguide 34, will generate electron-hole pairs, and correspondingly convert radiation back to electrical signal through electron hole separation and voltage biasing.

In FIG. 24 one reverse biased junction is supplied by an abrupt pn junction 160. Avalanche multiplication and relaxation processes in this junction yield photonic radiation in the 450-650 nm wavelength region and exits along the waveguide 34. When the voltage bias of the junction is lowered, the depletion region goes in deep reverse bias with minimum of charge multiplication processes and no photonic generation. Any incident radiation into the junction as arriving along the waveguide 34 will hence generate additional electron hole pairs and additional charge multiplication processes leading to an enhanced receiver at the detection terminals of the device. A third body 162 can be added to the device that will change the electric field profile at the abrupt pn junction 160 and cause modulation or intensity variation of the photonic generation process through modulation signal input 164.

In a second version of the invention is described by means of FIGS. 25 (a) and (b). Here a plan schematic diagram of a proposed CMOS waveguide based signal transmit-receive module 170. The module can convert electrical input signals to optical signals that are transmitted by the CMOS waveguide 34. Similarly, the module 170 can convert signals that arrive by waveguide 34 to electrical signals by means of photonic absorption processes in a silicon well. A terminal 172 located within the well region can detect transverse currents as generated in the well region and provide a signal output terminal. The module is optimised to operate at 750-850 nm wave length, which is a low loss region for CMOS based waveguides utilising silicon nitride or Silicon oxi-nitride. FIG. 7 (b) shows the corresponding components in cross-section view. The 750 nm radiation is generated by means of a special process where charges are generated at a excitation control region (690), the excited carriers are then transferred through the well region 158 and injected into a third region/body 176 of higher doping where the transferred high energy carriers recombine with charge carriers of opposite charge type and yield photonic radiation of higher wavelength. By controlling the bias voltage on the third body 176, the wavelength of the generated photonic radiation 10 can be changed. Intensity control can occur by means of voltage biasing of the first body or by inserting a forth body in the well region such that it varies or modulates the density of transferred carriers into the third body 176. Both intensity as well as frequency modulation can hence be achieved with this device. FIG. 25 (b) shows a cross-sectional view of all the components.

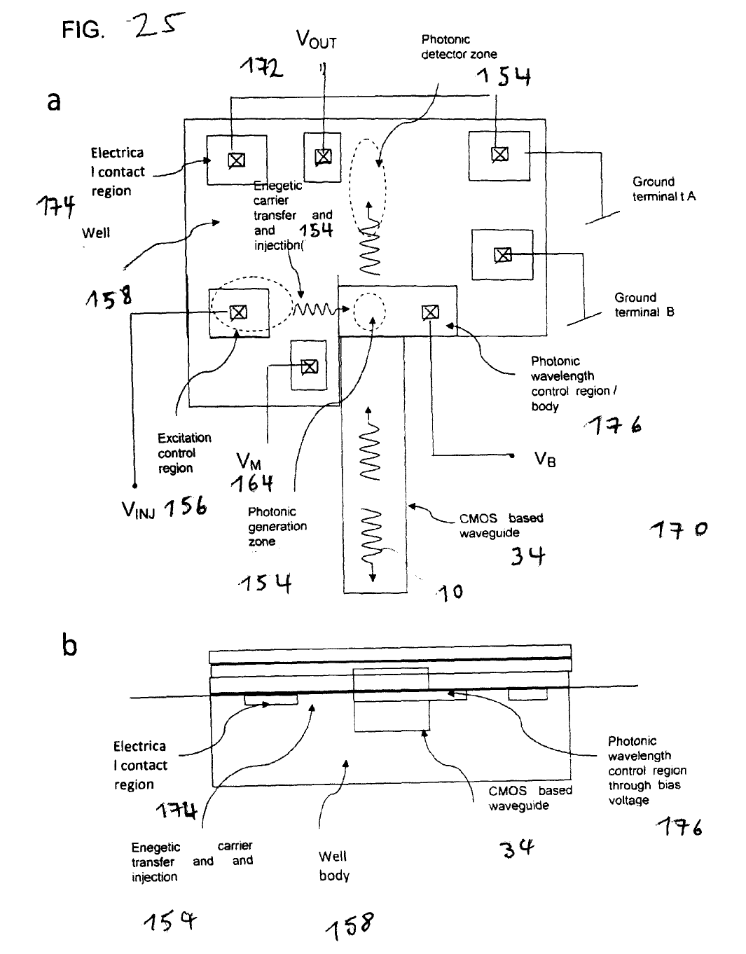

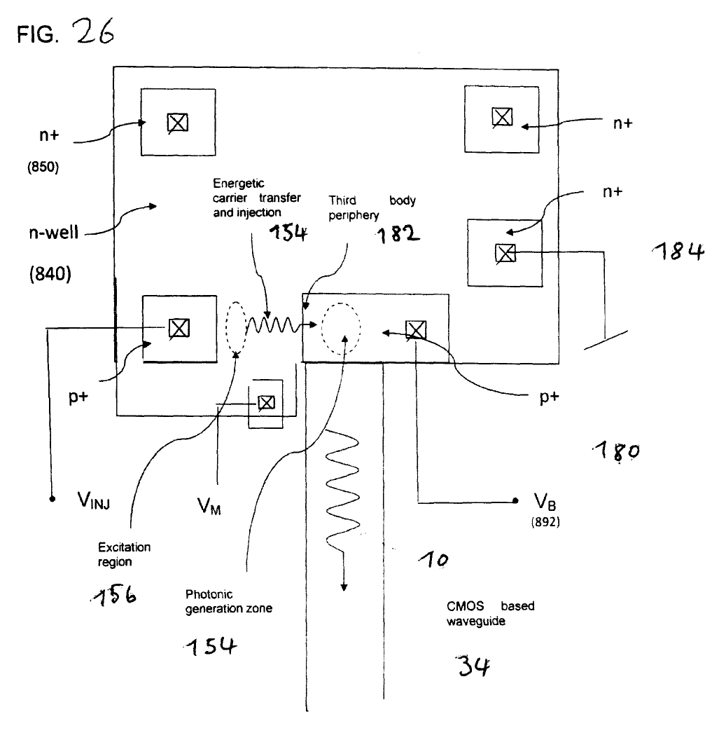

FIG. 26 shows a plan schematic diagram of an embodiment of the proposed CMOS waveguide based transmit-receiver module as in FIG. 7 operating in the signal transmit-mode of operation. Energetic carriers are generated in an excitation zone 156. The excited high energy carriers are then transferred to a third body 180 and injected into the third body where they recombine with a high density of opposite charge carriers and generate photonic radiation in the 750 nm regime. The periphery of the third body 182 provides a potential barrier which alters the energy of the injected carriers as they are injected through the periphery and alters the wavelength of the emitted radiation. The ground terminal 184 is strategically placed in order to provide correct and directive electric field such that the excited carriers are transferred towards the third body periphery 182. Appropriate voltage biasing is applied on the various terminals as indicated.

FIG. 27 shows a plan schematic diagram of an embodiment of the proposed CMOS waveguide based signal transmit-module operating in the receive mode. A voltage bias is applied to the p+ third body region 190 reverse biasing the region in the lightly doped n-well over a large proportion of the n-well and as facilitated by the ground terminals. As photonic radiation impinges into the well region 192 from the waveguide 34, the radiation is absorbed in the n-well region and generates electron hole pairs. These charges are separated by the lateral electric field in the well 192 and can be detected by a third terminal 196 which is strategically placed in the n-well 192 and provide as a voltage read-out signal. Alternatively the current supplied to the n-well through the bias terminal 194 can also be used as an output signal.

FIG. 28 shows a plan schematic diagram of a further embodiment of the invention through a proposed CMOS waveguide based signal transmit-receive module that consist of a central waveguide 34 and separated transmit 202 and receive modules 200. The module is optimised to operate at 750-850 nm wave length, which is a low loss region for CMOS based waveguides utilising silicon nitride or Silicon oxi-nitride.

In the following, a photonic crystal system will be described which can be used as a further building block in a micro photonic system 2.

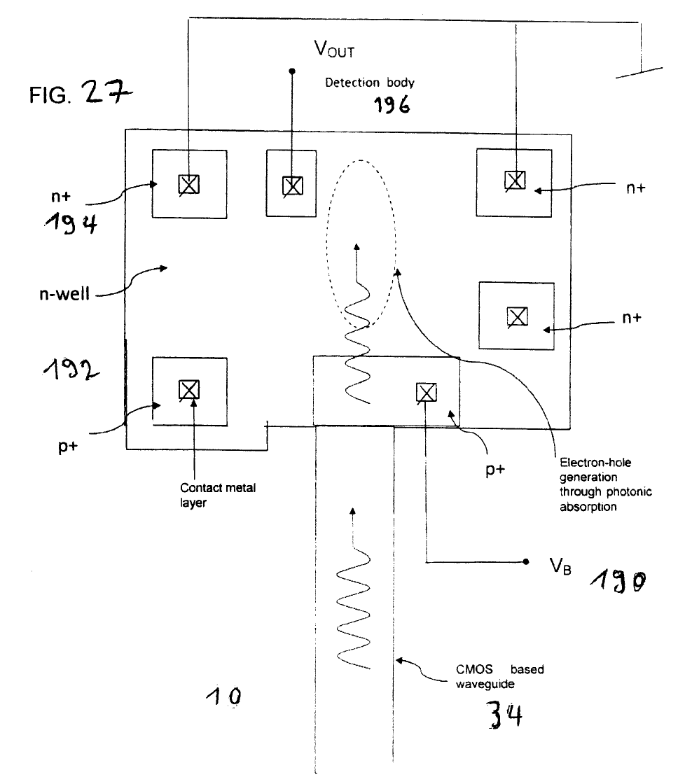

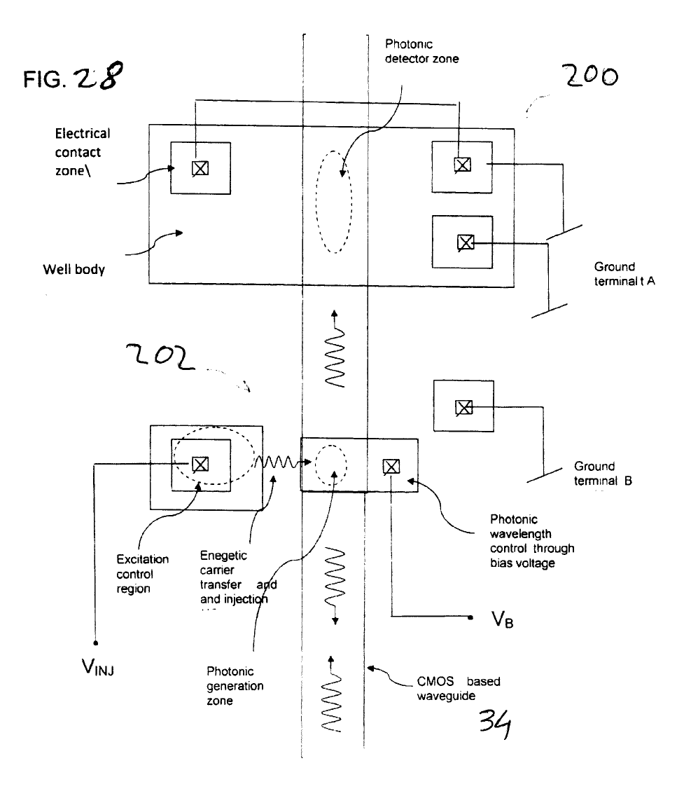

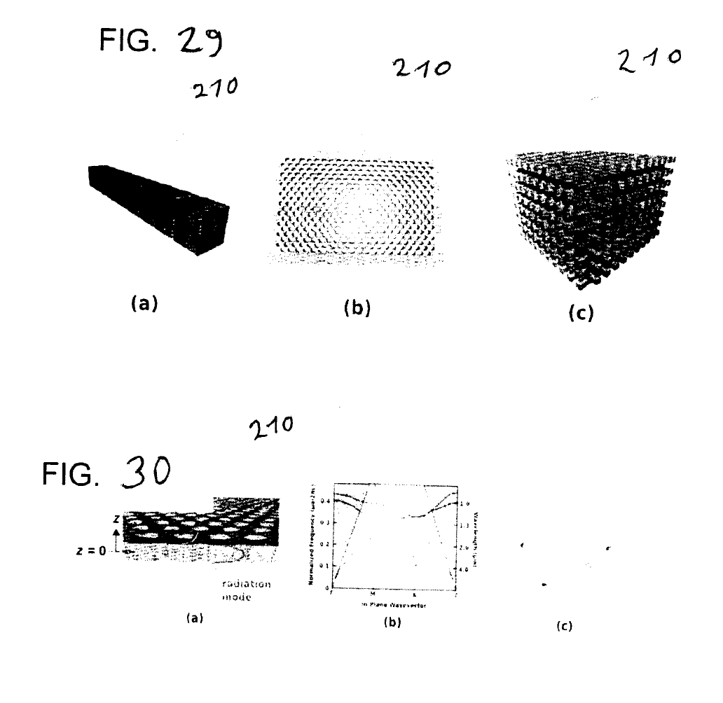

FIG. 29 shows schematic diagrams depicting photonic crystals 210 with periodicity in (a) one dimension, (b) two dimensions and (c) three dimensions.

FIG. 30 (a) shows a cross section of the two-dimensional photonic crystal 210 defined in a dielectric slab of finite thickness. The field distribution in the vertical direction for guided and radiation modes are shown. FIG. 30 (b) shows a photonic band diagram for the two-dimensional photonic crystal 210 defined in a single-mode slab. The diagram depicts the lowest three bands for the TE-like modes of the slab. The inset shows the region of the first Brillouin zone described by the dispersion diagram. FIG. 30 (c) shows a unit cell of a triangular photonic crystal lattice and the phase relationships between the boundaries determined by Bloch's theorem.

Some key aspects as associated with photonic crystal structures are as follows. Basically, either, one dimensional, two dimensional photonic crystals 210 can be generated that can sustain wave propagation in these crystals. Of particular interest is the generation of two dimensional planar crystals that can sustain linear waveguides as is illustrated in FIG. 29 (b). The basic concept of operation is that a matrix of holes is processed in a film of higher refractive index material. The density of holes per unit area is varied such as the a larger unit volume of air in some regions than other non hole containing areas, with resultant that propagating waves sees a lower refractive index in regions that contain less holes. Hence regions or wave guides can be generated in the “photonic crystal” 210 such created. This can hence sustain the confinement and propagation of planar waves in a certain direction along the crustal.

The photonic band-gap of the photonic crystal 210 shown for silicon on oxide (SOI) structures as illustrated in FIG. 30 corresponds to the normalized frequency range 0.25-0.32 where there are no propagating modes in this structure. Using a lattice constant of a=400 nm places the near infrared fiber optic communication wavelengths of 1.3 μm (low-dispersion) and 1.5 μm (low-loss) within the band-gap making this geometry amenable to applications in fiber optic communication systems. The shaded regions on the left and right sides of FIG. 30 (b) represent the projection of the light cone onto the various propagation directions which is a result of the vertical confinement mechanism being due to index guiding. Photonic crystal modes that overlap the shaded regions in FIG. 30(b) correspond to the radiation modes in FIG. 30 (a). FIG. 30 (b) shows the dispersion for the three lowest frequency bands with transverse electric polarization (out-of-plane magnetic field has even vertical symmetry). FIG. 30 (c) illustrates a unit cell corresponding to a triangular lattice photonic crystal. Photonic crystal geometries represent complicated electromagnetic problems.

Similar to the micro photonic system of FIG. 1, light signals can be directed from the photonic crystal plane to interact with specific exposed regions to the environment by creating a optical cavity and sensor area in the outer passivation layers of the CMOS structure. These can include specifically designed sensor areas where optical radiation can interact with gases, fluids, particles, and even mechanical modules. Certain intensities changes or wavelength detection changes can be observed in the cavity region such as signal absorption, optical reflection phenomena and even fluorescence phenomena can add specific intensities at new wavelengths to the observed and detected radiation in the cavity region.

This is now further described in FIG. 31 which is a schematic illustration showing how a multiple processing layer configuration (MPLC) can be formed in CMOS silicon consisting of several individual processing layers stacked on top of each other. In the specific case illustrated, a passivation and slotted passivation topmost layer 212 is stacked on a photonic crystal plane layer 210 which is again stacked on the conventional electrical interconnect and electrical signal processing and data transfer layer 214. In the case of the photonic layer 210, a slab of higher refractive index material which can accommodate discrete wave guides, a combination of discrete waveguides, or an entire photonic crystal layer including a matrix of holes stacked in the higher refractive index material causing variation in the local refractive index of the layer.

Hence a three layer advanced Silicon CMOS integrated circuit module basically consist of three different data and signal processing planes: the sensor or environmental interfacing plane 212, the so called photonic processing plane 210 where the data is optically amplified, analysed and directed to different venues; and an electrical signal and data processing plane 214, where the optical data is converted to electrical pulses and data and these then processed and channeled and stored according to conventional means. In further embodiments, a fourth plane may be generated where processed and accumulated data are stored in a dedicated memory plane.

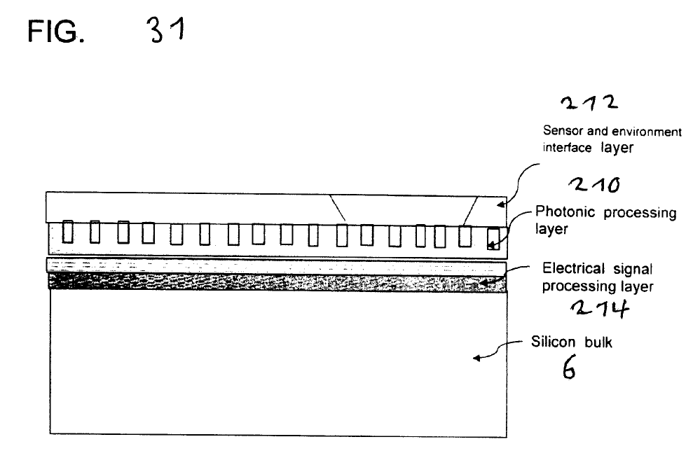

In the photonic plane, a variety of signal and wavelength processing functions may be imposed. These concepts are schematically illustrated in FIG. 32. Firstly, a broad spectrum source may be divided up into a variety of individual narrow band wavelengths using standard ring oscillator, or filtering techniques. A so called bus bar 216 may be created that connect various regions and subsystems to each other and through which a number of different signals of different wavelengths may propagate. Using ring waveguide structures, a modulator 220 may be generated in the photonic crystal waveguide, which can modulate the propagating waveguide either in the bus bar or in secondary waveguide bars. Some of the modulators may utilize an electric input signal from the CMOS electrical interface plane.

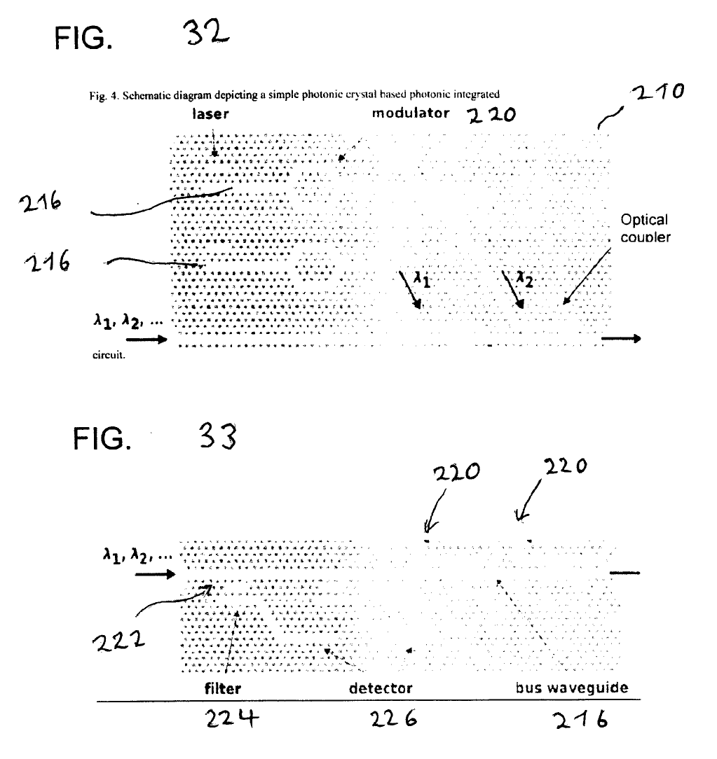

FIG. 33 describes the generation of an optical bus waveguide (bus bar) in the photonic crystal layer. The illustration shows a top down view on the photonic processing plane 210, showing the array of holes in the higher refractive index slab. Waveguides and various individual components are formed in the photonic layer in integrated circuit format. In the specific case the concept of removing certain wavelength signals from the optical bus bar by means of optical couplers and diverting them to secondary detectors are illustrated.

Using secondary optical or even laser structures, secondary modulators may be introduced as illustrated in FIG. 33 in secondary waveguide branches and then mixed with bus bar waveguides by means of coupler structures 220 where two waveguides are positioned close to each other enabling coupling of their respective propagation fields. In other cases, radiation may be extracted from the bus bar and diverted into side branch waveguides through coupler structures 222. Secondary filtering 224 or even detection of radiation 226 as well as direct coupling with electrical circuitry below in the CMOS electrical plane 214 may occur.

Hence advanced optical sensing including compositional, elemental, physical parameters of gases fluids, and particles as well as mechanical parameters such as vibration, defection and acceleration can be determined with the module.

In other embodiments, the bus bar or other waveguides 216 may directly interface with the side surface of the chip die and enable ultra-fast and efficient optical coupling with a single optical fibre or array of optical fibres situated at the side surface of the photonic crystal. In other embodiments, adiabatic expansion techniques may be utilised to provide an optimum coupling with the core of the optical fibres. In other embodiments, the waveguide at the side surface may incorporate a two dimensional lens like structure so as to generate advanced columniation or focusing of the emerged optical radiation at the side surface.

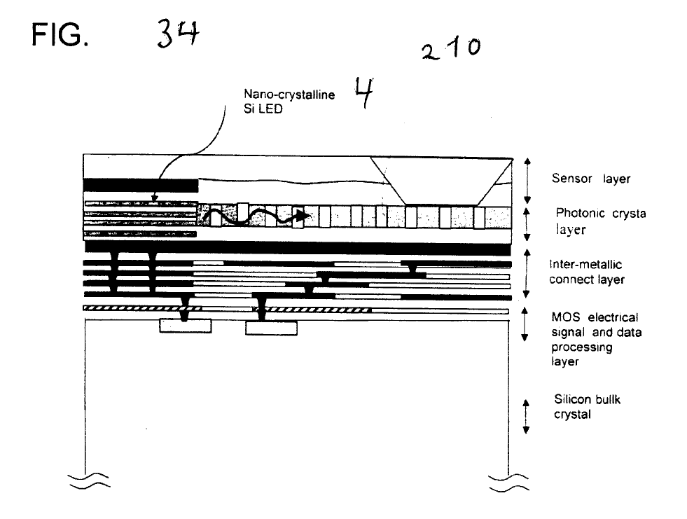

FIG. 34 shows a schematic diagram of an example CMOS-based Micro-Optical Sensor module that utilize a nano-crystalline Si LED device 4 in the outer layers of the module such that it couple optimally in the same plane with the photonic crystal lattice 210.

In this embodiment of the invention, a nano-crystalline based Silicon LED (nc Si LED) may be used as optical source 4 and positioned such that it interfaces closely with one side face of the photonic crystal 210, as is schematically illustrated in FIG. 34. In this case, a high optical coupling efficiency is achieved together with the utilization of a much higher optical power than achievable with Si Av LEDs.

However modulation speed of nc Si LEDs are limited. Modulation of the optical radiation can be achieved by means of modulation of the propagating beam in the photonic crystal 210 by introducing specialized modulation structures in the photonic crystal. Very low optical power consumption may be achieved per bit by using photonic crystal 210 based modulators. Alternatively optical modulators may be in the wave propagation plane by insertion of discrete foreign material modulators inserted from the top surface of the module, so that it is situated of the propagating beam of the photonic crystal. Similarly suitable nano-crystalline detectors can be placed on the other side face of the photonic crystal, which will enable detection of radiation in the same plane at also a very high coupling efficiency.

In other embodiments the photonic crystal plane may be positioned just above the MOS electrical processing layer in the structure in order to ensure a more intimate contact of the nano-crystalline LED with n or p regions in the silicon bulk. In such cases Electrical processing regions and photonic crystal planes, in this case, may be stacked vertically closer with only discrete metal contacting in certain regions' of the electrical data processing layer. In some cases the photonic crystal layer and the Electrical MOS data processing layer may be accommodated in the same plane, but laterally displaced from each other. It is assumed that the planar top down views of the photonic crystal structure as described here will be the same as outlined in FIG. 32 and FIG. 33. The emission wavelength of the n-c Si LED may be either 750 nm or at 1550 nm. In other embodiments of the invention, Si LEDs 4 may be designed and implemented for the above purposes that operate in the forward biased pn junction mode and that emit at 1100 nm.

In other embodiments of the invention, where the photonic crystal 210 operates with above 1000 nm wavelengths, suitable resonator and frequency doubler circuits may be implemented in the crystal so as to cause a down conversion of the optical signal to a below 1000 nm signal, such that it can be detected with standard silicon detectors.

In other embodiments of the invention, the silicon optical source 4 may be fabricated from silicon, but the photonic crystal be designed and implemented such that it couples with the optical source in the same plane. CMOS Silicon on Insulator (SOI) technology may be suitable carrier technology for such an implementation.

In other embodiments of the invention, the optical source may be hybridly placed in a pre-fabricated air slot either from the top or bottom surface of the die, such that it couples with the photonic crystal plane. In such cases CMOS or CMOS SOI technology may be main motivation technology to implement such a configuration. This technique may also apply for placing a high intensity ultra-violet or other source in the sensor cavity in the outer surface layers of the module.

In the following an example for a Si Av LED as optical source 4 is described in more detail.

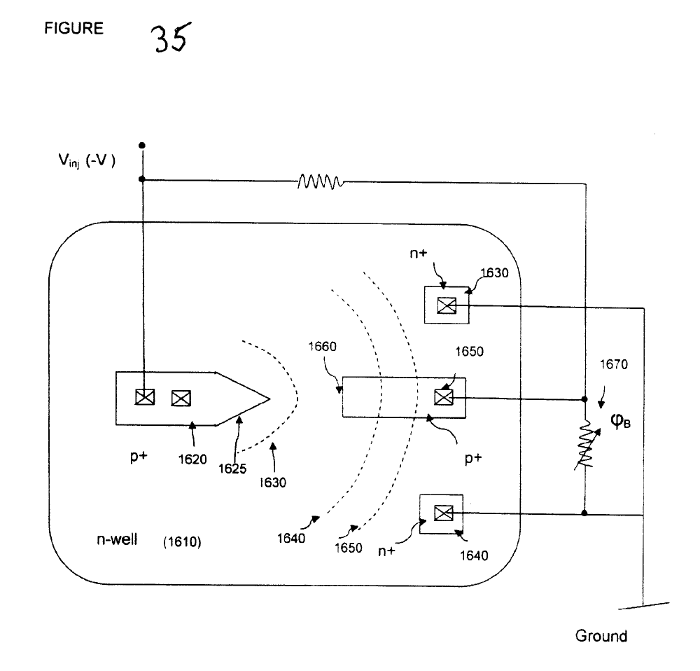

FIG. 35 shows a further embodiment of the invention where the second junction 1650 is placed deep into the depletion region of the first junction 1620, and a particular contact and voltage biasing are applied in order to produce a energy barrier for traversing energetic carriers at the second junction 1660. The depletion region in the lower doped n-material extends a large distance towards the secondary bias contact configuration 1630, 1640 and 1650. The electric field strength also decreases towards this direction. Towards the border region 1630 the electric field is high enough in order to sustain impact ionisation and multiplication of carriers. Towards the border 1640 the electric field is high enough in order to sustain charge scattering near the threshold energy required for impact ionisation but impact ionisation does not occur. From border 1640 to 1650 the electric field strength is low and the average energy of the electrons are much lower than the threshold energy required for impact ionisation. The second abrupt p+n junction is placed in between 1630 and 1640 where the average energy of carriers is near to the threshold required for impact ionisation, i.e. 1.8 eV.

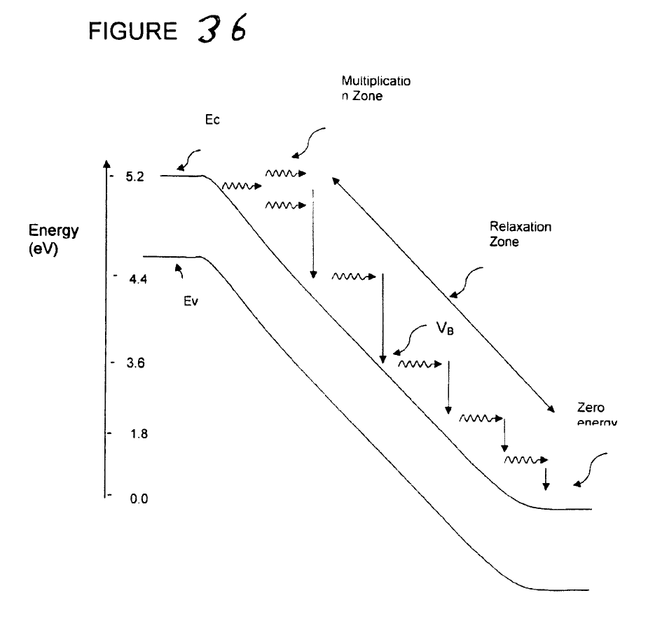

FIG. 36 shows a projection of the average diffusion length versus energy loss transitions for electrons in the conduction band as a function of distance in the depletion layer of an abrupt p+n junction. It is seen that the average energy distribution of the electrons in the region between borders 1630 and 1640 is projected to be in a distribution function between 1 and 2 eV with a peak at 1.5 to 1.8 eV.

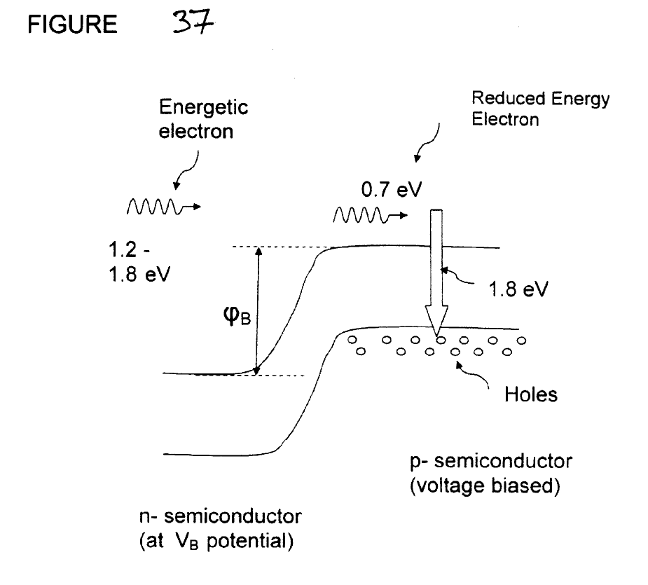

FIG. 37 shows a projection of how the energy of the injected energetic (hot) electron can be lowered when it is injected into the biased potential barrier of the second reverse biased p+n junction, 1660. The subsequent recombination of the injected electron with a high density of holes as present on the p-side of the junction is also shown. This recombination between the lowered energy electrons and the high density of holes results in photonic emissions from the device. Since the average energy of the injected carrier into the p-side of the second junction can be varied as a function of bias voltage of the second junction, it implies that the photonic emission wavelength can be varied. The device configuration of position of the second p+n junction in the depletion layer as well as the voltage biasing of the light hence implies that the emission wavelength of the device can be tuned to have a peak in the wavelength region 650 nm to 850 nm.

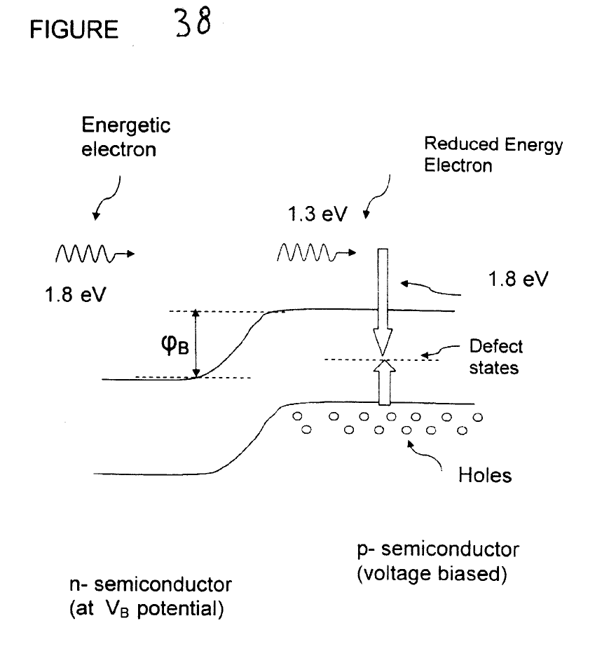

FIG. 38 shows a projection of how the energy of an energetic (hot) electron can be lowered when it is injected into a biased potential barrier of e second biased p+n junction. The subsequent recombination of the injected electron with a high density of holes on the p-side of the junction is also shown, when defect states are present in the junction. Since the energy levels of defect sates that is highly active as recombinational states normally lies mid-band, it implies that a lower energy barrier has to be set up for the second junction, in order to attain a photonic emission wavelength of 650-850 nm. The photonic emission intensity and electrical-to-optical conversion efficiency may be higher with the mid-bandgap defect states.

It can be appreciated that other embodiments of the invention with slight variations in structure and position of the second junction are also possible. These are all considered of being within the scope of the invention of obtaining a tuned emission CMOS compatible silicon light emitting device through carrier injection into a second potential barrier.

In other embodiments of the invention, a thin layer of very low doping level may be introduced in the region between the junction 1625 and the first border region 1630 in FIG. 35, such that more multiplication lengths of electrons can be accommodated.

In other embodiments of the invention, a thin layer of n semiconductor material may be embedded in the body 1620 of FIG. 35. This body may be voltage biased such that low energy electrons are injected into the junction at 1625 and accelerated through the region between 1625 and the border region 1630. This will allow lesser or no ionisation processes to occur in the region between 1625 and 1630 while the same energy excitation and photonic recombination processes are occurring in the rest of the device.

In other embodiments of the invention, the doping types as indicated in the device in FIG. 35, may be changed to a opposite type, i.e. n-type is changed to p-type and p-type is changed to n-type in order to obtain specific effects

In other embodiments of the invention, the doping levels of the second junction 1660 may be changed in order to obtain specific energy changes in the carriers, e.g. varying the doping levels such that either a laterally wide or a laterally very narrow barrier occurs in the carrier traverse direction.

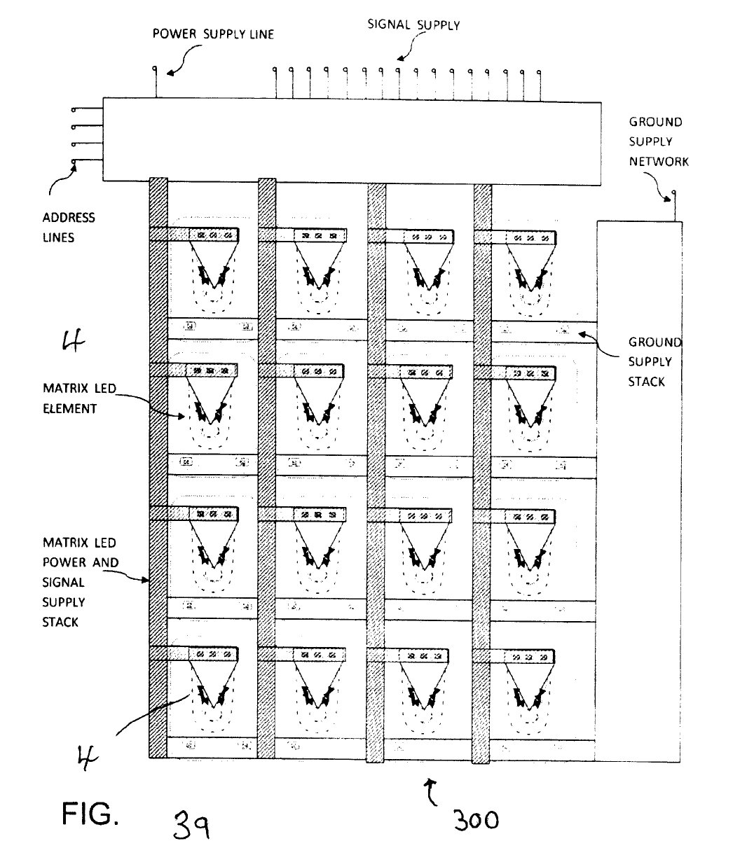

An array of light source elements using the light source 4 as described above are, are arranged in matrix form 300 in a substrate of lower conductivity type as shown in FIG. 39. The number of light source elements incorporated in the matrix is optional, but is mainly a function of the number of metal over-layers that can be offered by the particular processing technology in order to individually electrically access each element.

The high conductivity substrate bodies of each matrix element could be merged with adjacent elements if maximum compactness of the matrix is required. However, this may result in reduced signal isolation between adjacent elements and more cross talk interference.

A common ground supply network is supplied to each matrix element by means of typically a metal 1 line feed arrangement as shown in FIG. 39. If the process allows multi-stack layering of more metal lines, further individualized access to elements can be provided to single elements or group of elements.

Individual electrical access to each matrix light source element is provided by a multi-metal layer stack as shown in FIG. 39, supplying electrical supply voltage and current to each element with contact holes through the metallization and oxide interface layers as are illustrated.

The electrical supply voltage and signal modulation is supplied by a suitable address line and single signal supply lines offering single or multiple access to the matrix elements as are currently possible with current code addressing and signal multiplexing technology as proposed in FIG. 39.

The last exemplary embodiments deal with RF and IR signal capabilities of the micro photonic system 2 and some general applications.

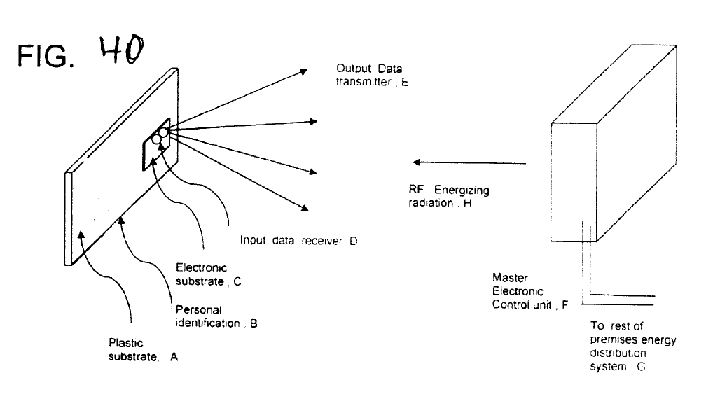

FIG. 40 illustrates principles as associated with this embodiment of the invention. The main inventive concept deals with using a plastic user card or mobile module platform, A, (comparable to credit card used for banking purposes) with printed personal identification, B, on it. On the plastic platform is pasted or embedded a electronic substrate, C, that contains a input data receiver, D, and a output data transmitter, E, that transmits data to a master electronic control unit, F. The master electronic control unit receives the data from the user card and then performs subsequent electronic processing of the data. The result of the master electronic unit data processing can be used for various purposes.

Firstly, for (1) personal identification of the user card and comparing it with data lists on record in the master unit; (2) for customization purposes of mobile commodities such as mobile vehicles; or (3). for customization of fixed assets and premises, or (4) for energy management of either mobile vehicles or fixed asset premises (such as for example switching on and off lights in a certain configuration); or (5) for any other customization setup. The user card can either be energies by means of on board batteries, solar photovoltaic cells or by RF energizing radiation. The user card can be preprogrammed with appropriate Identification, configuration setup, customization setup from any other programmable device such as a laptop using existing data communication technologies such as Blue Tooth or infrared links.

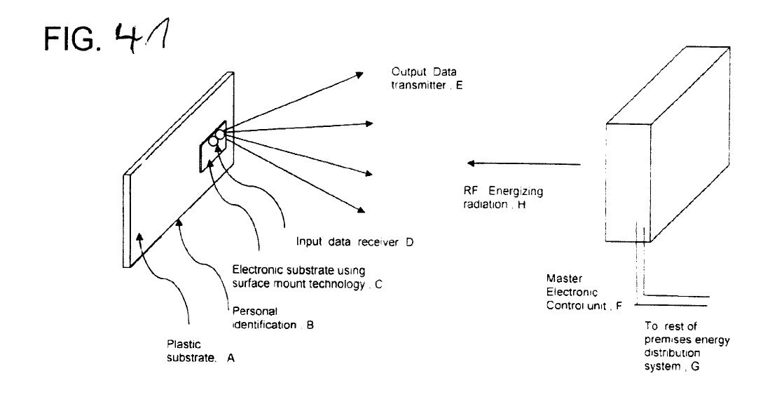

In a first embodiment of the invention as shown in FIG. 41, a micro RF oscillating and transmitting circuit and electronic driving and processing circuitry is fabricated on a printed circuit board platform using surface mount technology. The RF transmitting pattern is designed that is extremely wide angle or even omni-directional. The frequency is chosen to be in one of the permissible MHz or GHz bands. The dimensions of the total circuitry may in this case be bigger but it is envisaged that it will still be within credit card dimension limits. The RF transmitting pattern is designed that is extremely wide angle or even omni-directional. The frequency is chosen to be in one of the permissible MHz or GHz bands. The 2-20 GHz bands are particularly attractive since very small oscillating circuitry can be directly fabricated at micron dimensions on CMOS chip using lateral inductor and reverse bias capacitance or avalanche-capacitance technology. The transmitting carrier is appropriately modulated with on board CMOS modulation circuitry. Appropriate coding techniques can be used to transmit programmable and instructional information from the user card to the Master unit. The Master unit receives the information and can be coupled to secondary control circuitry. This unit can hence perform certain secondary tasks such identification of the user card and person, perform customized set up functions of a mobile vehicle, or set up customized energy management functions in a local premises, or any other control function. The Master unit radiates radiating RF energy which is absorbed on the card by means of a suitable antenna, the energy is rectified and used to charge a on board local capacitor or battery. The transmitting circuit only operates if the on board stored energy has reached adequate levels. The advantage of using RF communication techniques is that the card needs not to pointed directly to the master unit and it can operate in any position within a certain range from the master unit, even from within the pocket of a user person.

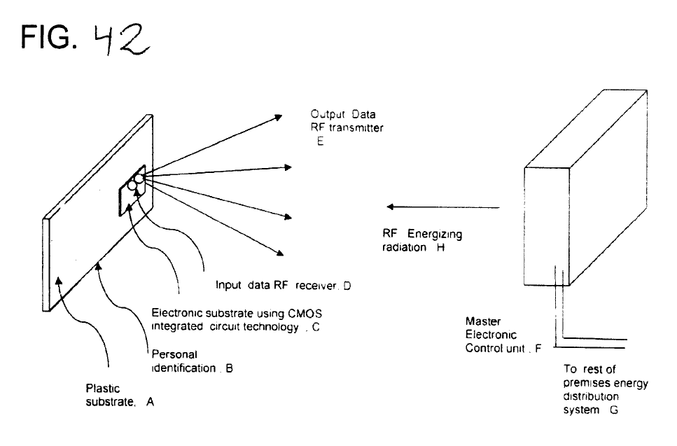

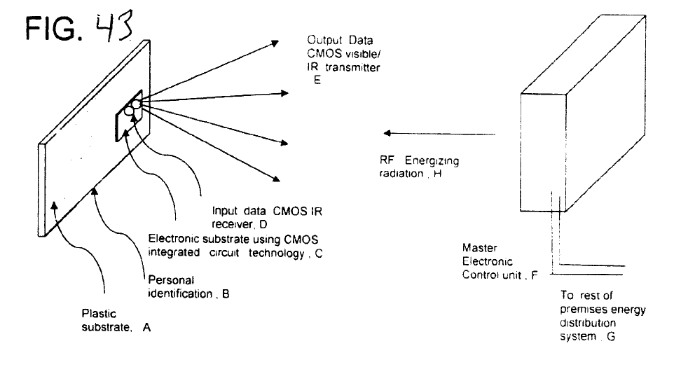

In a third embodiment of the invention as shown in FIG. 42, a micro RF oscillating and transmitting circuit is fabricated on a CMOS chip platform. The RF transmitting pattern is designed that is extremely wide angle or even omni-directional. The frequency is chosen to be in one of the permissible MHz or GHz bands. The 2-20 GHz bands are particularly attractive since very small oscillating circuitry can be directly fabricated at micron dimensions on CMOS chip using lateral inductor and reverse bias capacitance or avalanche-capacitance technology. The transmitting carrier is appropriately modulated with on board CMOS modulation circuitry. Appropriate coding techniques can be used to transmit programmable and instructional information from the user card to the Master unit. The Master unit receives the information, can be coupled to secondary control circuitry. This unit can hence perform certain secondary tasks such identification of the user card and person, perform customized set up functions of a mobile vehicle, or set up customized energy management functions in a local premises, or any other control function. The Master unit radiates radiating RF energy which is absorbed on the card by means of a suitable antenna, the energy is rectified and used to charge a on board local capacitor or battery. The transmitting circuit only operates if the on board stored energy has reached adequate levels. The advantage of using RF communication techniques is that the card needs not to pointed directly to the master unit and it can operate in any position within a certain range from the master unit, even from within the pocket of a user person.

In a fourth embodiment of the invention as shown in Figure embodiment of the conceptual generic principles as associated with this invention using directional optical infrared radiation. Utilising this technology will enable extremely small micro-dimensioning of circuitry and chips, which will increase functionality, reduce system dimensions, reduce the cost of such systems and increased mass production capabilities. A micro IR emitting circuit is fabricated on a CMOS chip platform. The IR transmitting pattern is designed that is sufficiently wide angle so that a Master control unit detects the emitting radiation at ease when the card face is directed towards the master unit. The transmitting carrier is appropriately modulated with on board CMOS modulation circuitry. Appropriate coding techniques can be used to transmit programmable and instructional information from the user card to the Master unit. The Master unit receives the information, can be coupled to secondary control circuitry. This unit can hence perform certain secondary tasks such identification of the user card and person, perform customized set up functions of a mobile vehicle, or set up customized energy management functions in a local premises, or any other control function. The Master unit radiates radiating RF or IR energy which is absorbed on the card by means of a suitable antenna or detector, the energy is rectified and used to charge a on board local capacitor or battery.

The transmitting circuitry in all the above embodiments only operates if the on board stored energy has reached adequate levels.

Apart of using CMOS technology to realize the above devices, state of the art current silicon or silicon on insulator (SOI) technology can also be utilized the realize these devices. In this application separate higher refractive index and higher nitride based layers may be added to existing SOI layers in order to facilitate such devices.

Both Si Av LED technology as well as Organic LED and CMOS technology or other hybrid forms of technology can be incorporated as optical sources on the CMOS platform. Si Av LEDs offers the lowest cost as well as most monolithic fabrication. Where appropriate, high frequency RF techniques and circuitry can be incorporated, in order to further enhance efficiency of the system or in order to expand the generation and range of sensor systems.

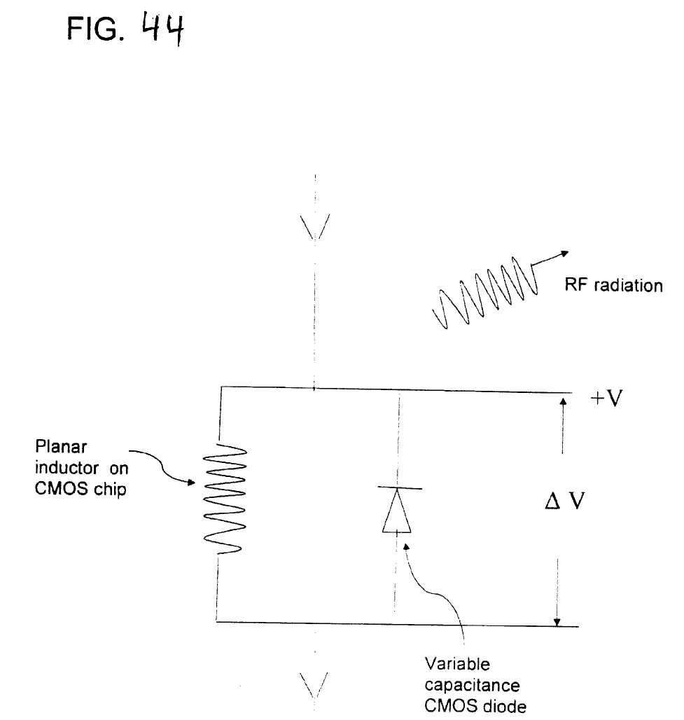

A method of generation higher efficiency radiation sources is by designing special high frequency oscillation circuitry in CMOS integrated circuitry. FIGS. 44 to 46 demonstrate a few examples.

In FIG. 44 a planar CMOS inductor layout is connected in parallel with a small CMOS diode layout. This forms a inductor-capacitor oscillator configuration of which the frequency can be tuned by varying the voltage across this parallel network through capacitance variation as associated with the CMOS reverse biased diode. The oscillating network can be coupled to an appropriate antenna element layout, either on CMOS or separate. The very small micro-dimensions as enabled by CMOS technology may facilitate radiation into well into the GHz range.

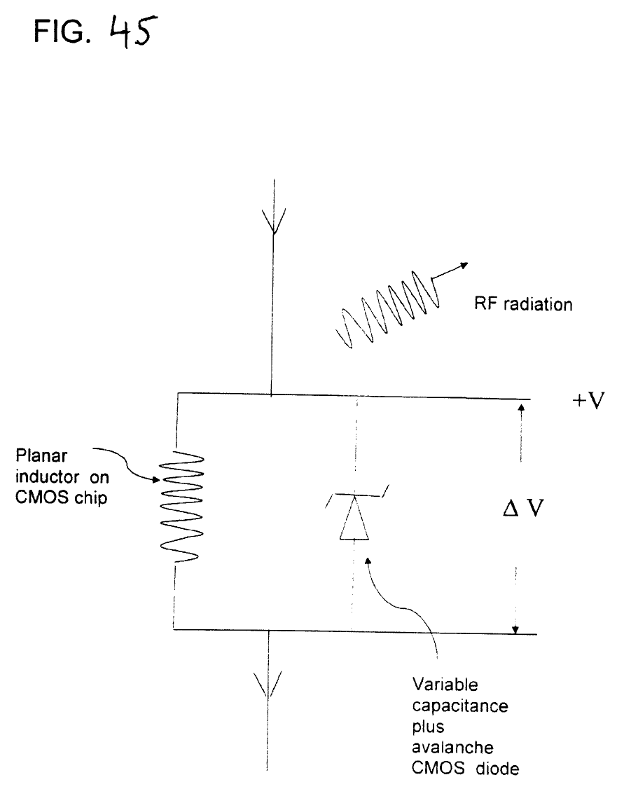

In FIG. 45 a planar CMOS inductor layout is connected in parallel with a small CMOS avalanche diode layout. This forms a inductor-capacitor oscillator configuration of which the frequency can be tuned by varying the voltage across this parallel network through capacitance variation as associated with the CMOS reverse biased diode. The oscillating network can be coupled to an appropriate antenna element layout, either on CMOS or separate. The very small micro-dimensions as enabled by CMOS technology may facilitate radiation into well into the GHz range. As the voltage difference is raised across this network the diode can be pushed into avalanche breakdown mode of operation. In this mode of operation the current pulses as caused by avalanche multiplication may drastically increase the current oscillation in the parallel network as well as in the antenna element. The higher current will drastically increase the radiation energy level. This energy is effectively supplied by the voltage power source. It is anticipated that the power to radiation conversion efficiency in this network could be very high.

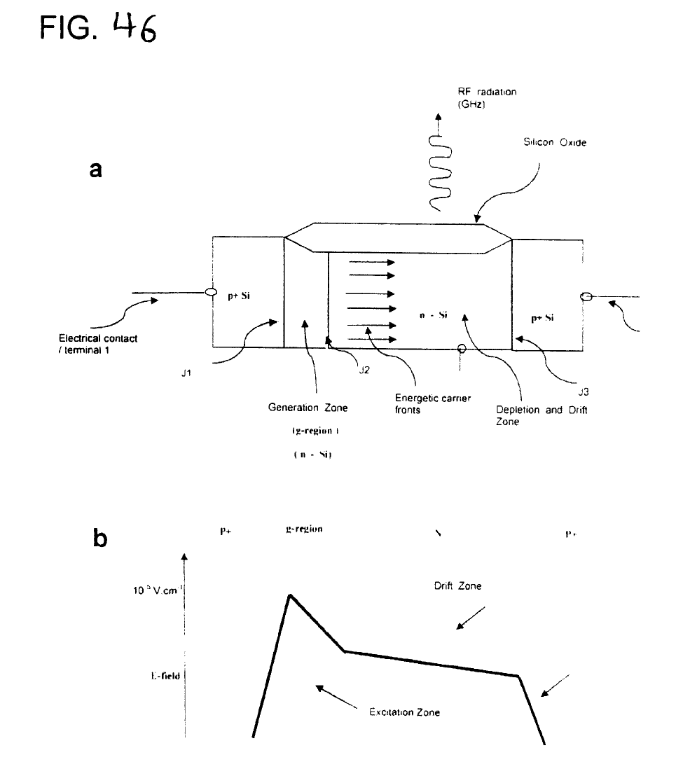

FIG. 46 demonstrates a three-bodied device is illustrated with body 1 of high doping, body 2 of medium doping, body three of low doping and body 4 of high or medium doping. Three terminals are fabricated to strategic regions of the device such that the junction between body 1 and body 2 are strongly reverse biased, and the junction between body 2 and three either kept at slight reverse, neutral or forward bias. If the doping profile is made p⁺np from body one to three, electrons will be excited at the first junction and because of the strong electric field between junction 1 and junction 2, drifted across the body two region and three regions and deposited into the body four region. The voltage variation and drift speeds as associated in the body three region will set up an oscillatory behavior in the device with current pulses moving sequentially through the device. If the device is coupled to a radiating antenna element these current pulses can ensure high radiation efficiency from the device. Alternatively an oxide layer can be facilitated on top of the structure which ensures low absorption efficiency for the radiation in the oxide layer and therefore ensures a high vertical out RF radiation efficiency for the device. The CMOS dimensioning again can facilitate the radiation frequencies to well within the GHZ range. The specific device is comparable to bulk IMPATT diode configurations. The power to radiation conversion efficiencies as associated with such devices range up to 50% efficiency.

The RF radiation will also ensures a wider angle radiation pattern from the chip platform at higher energies which may enable less directional dependency of the user card or mobile module.

1. A micro photonic system comprising an optical source, means for optical transmission, and a detector, wherein the optical source is capable of emitting light having a wavelength being in a range in which a nitride comprising layer of said means for optical transmission is transparent and being below a detection threshold of said detector so as to enable the generation of a micro-photonic system in silicon integrated circuit technology, wherein said means for optical transmission comprises a silicon-nitride core strip as a multi-mode electromagnetic radiation transporting medium which is embedded in silicon-oxide through which a part of the electromagnetic radiation is propagating and lateral optical coupling means as wave guides in which the optical radiation can be converted from multi-mode propagation mode to single mode propagation mode by mode converters.

2. The micro photonic system according to claim 1, wherein said circuit technology is complementary metal oxide semiconductor technology (CMOS) silicon integrated circuit technology and said means for optical transmission are either fabricated in CMOS over-layers or in CMOS isolation trenches.

3. The micro photonic system according to claim 2, wherein said wavelength is in the range between 600 nm and 900 nm.

4. The micro photonic system according to claim 1, wherein said means for optical transmission include an optical coupling component, a wave guiding component, a reflective component, or a refractive lens.

5. The micro photonic system according to claim 1, further including a detector component that provides for an intensity change in the detector and can enable measurement of physical and chemical parameters such as temperature, shock, motion, acceleration, light level, fluid flow, and particle counts and particle absorption and particle fluorescence, or utilizing intensity or phase contrast technology.

6. The micro photonic system according to claim 1, wherein the light source is an integrated Si Av LED.

7. The micro photonic system according to claim 1, wherein the optical source is separated from a phase contrast optical module in order to increase sensitivity, accuracy and stability in measurement.

8. The micro photonic system according to claim 1, wherein the optical source is an OLED device being integrated into CMOS structures or being added hybridly to a CMOS fabrication process.

9. The micro photonic system according to claim 1, wherein the optical source and the detector form a waveguide based optical transmit receiver module including an excitation region generating excited high energy carriers, a carrier relaxation and recombination zone for the excited carriers yielding photonic emission, a photonic absorption region where incident photons as received from the waveguide generates electric current, and a junction region which generates additional electron hole pairs and additional charge multiplication processes leading to an enhanced receiver at the detection terminals of the device.

10. The micro photonic system according to claim 1, wherein the optical source is arranged as a matrix of Si Av LEDs on a silicon substrate.

11. The micro photonic system according to claim 1, further comprising a photonic crystal.

12. The micro photonic system according to claim 1, wherein the optical source is comprised of a body of a semiconductor material; a first junction region in the body formed between a first region of the body of a first doping kind and a second region of the body of a second doping kind; a second junction region in the body formed between the second region of the body and a third region of the body of the first doping kind; a terminal arrangement connected to the body for, in use, reverse biasing the first junction region into a breakdown mode and for forward biasing at least part of the second junction region to inject carriers towards the first junction region; and the device being configured so that a first depletion region associated with the reverse biased first junction region punches through to a second depletion region associated with the forward biased second junction region.

13. The micro photonic system according to claim 1, wherein the optical source and the detector form an optical communication system.
